(19) United States
(12) Patent Application Publication
(10) Pub. No.: US 2025/0393256 A1
(43) Pub. Date: Dec. 25, 2025

(54) SEMICONDUCTOR DEVICE AND METHOD FOR MANUFACTURING THE SEMICONDUCTOR DEVICE

(71) Applicant: Semiconductor Energy Laboratory Co., Ltd., Atsugi-shi, Kanagawa-ken (JP)

(72) Inventors: Masami JINTYOU, Shimotsuga (JP); Yukinori SHIMA, Tatebayashi (JP); Masataka NAKADA, Tochigi (JP); Kensuke YOSHIZUMI, Atsugi (JP)

(21) Appl. No.: 19/103,839

(22) PCT Filed: Sep. 1, 2023
(86) PCT No.: PCT/IB2023/058643

§ 371 Date: Feb. 14, 2025

(30) Foreign Application Priority Data
Sep. 8, 2022 (JP) 2022-142855

(51) Int. Cl. H10D 30/67; H10D 30/01; H10K 59/121

(52) U.S. Cl. CPC H10D 30/6757; H10D 30/0321; H10D 30/6745; H10K 59/1213

(57) ABSTRACT

A transistor that can be miniaturized is provided. A transistor having favorable electrical characteristics is provided. A semiconductor device includes a first to a third conductive layer, a first to a third semiconductor layer, and a first and a second insulating layer. The second semiconductor layer is provided over the first conductive layer, the first insulating layer is provided over the second semiconductor layer, the second conductive layer is provided over the first insulating layer, and the third semiconductor layer is provided over the second conductive layer. The first insulating layer includes an opening reaching the second semiconductor layer. The first semiconductor layer includes a portion in contact with the third semiconductor layer, a portion in contact with a side surface of the first insulating layer inside the opening, and a portion in contact with the second semiconductor layer. The second insulating layer covers the first semiconductor layer. The third conductive layer overlaps with the first semiconductor layer with the second insulating layer therebetween. The first to the third semiconductor layer contain silicon. The second and the third semiconductor layer contain the same impurity element. The first insulating layer contains hydrogen, nitrogen, and silicon.

### TECHNICAL FIELD

One embodiment of the present invention relates to a semiconductor device and a method for manufacturing the semiconductor device. One embodiment of the present invention relates to a transistor and a method for manufacturing the transistor. One embodiment of the present invention relates to a display device that includes a semiconductor device.

Note that one embodiment of the present invention is not limited to the above technical field. Examples of the technical field of one embodiment of the present invention disclosed in this specification and the like include a semiconductor device, a display device, a light-emitting apparatus, a power storage device, a memory device, an electronic device, a lighting device, an input device, an input/output device, a method for driving any of them, and a method for manufacturing any of them. A semiconductor device refers to any device that can function by utilizing semiconductor characteristics.

### BACKGROUND ART

Miniaturization of transistors has been required. For example, a display device in which a transistor occupies only a small area of a pixel can have downsized pixels, leading to high resolution. In addition, in such a display device, the number of transistors provided per unit area can be increased, that is, a large number of transistors can be provided in the pixel without increasing the pixel size, so that a correction function or the like can be added to the pixel, for example.

In recent years, the resolution of display panels has been increased. As a device that requires a high-resolution display panel, a device for virtual reality (VR) or augmented reality (AR) has been actively developed in recent years besides a tablet terminal, a smartphone, and a watch-type terminal. For a high-resolution display panel, a light-emitting element such as an organic electroluminescent (EL) element or a light-emitting diode (LED) is mainly used.

Patent Document 1 discloses a high-resolution display device that includes an organic EL device (also referred to as an organic EL element).

### REFERENCE

### Patent Document

[Patent Document 1] International Publication No. 2016/038508

### SUMMARY OF THE INVENTION

### Problems to be Solved by the Invention

An object of one embodiment of the present invention is to provide a transistor that can be miniaturized. Another object is to provide a transistor having favorable electrical characteristics. Another object is to provide a transistor whose channel length can be reduced. Another object is to provide a transistor that occupies a small area. Another object is to provide a display device that can easily achieve higher resolution.

Another object of one embodiment of the present invention is to provide a transistor, a display device, an electronic device, or the like that has a novel structure. Another object of one embodiment of the present invention is to provide a transistor, a display device, an electronic device, or the like that has high reliability. Another object of one embodiment of the present invention is to at least alleviate at least one of problems of the conventional technique.

Note that the description of these objects does not preclude the existence of other objects. One embodiment of the present invention does not necessarily achieve all of these objects. Other objects can be derived from the description of the specification, the drawings, the claims, and the like.

One embodiment of the present invention is a semiconductor device including a first conductive layer, a second conductive layer, a third conductive layer, a first semiconductor layer, a second semiconductor layer, a third semiconductor layer, a first insulating layer, and a second insulating layer. The second semiconductor layer is provided over the first conductive layer, the first insulating layer is provided over the second semiconductor layer, the second conductive layer is provided over the first insulating layer, and the third semiconductor layer is provided over the second conductive layer. The first insulating layer includes an opening reaching the second semiconductor layer. The first semiconductor layer includes a portion in contact with the third semiconductor layer, a portion in contact with a side surface of the first insulating layer inside the opening, and a portion in contact with the second semiconductor layer. The second insulating layer covers the first semiconductor layer. The third conductive layer includes a portion overlapping with the first semiconductor layer with the second insulating layer therebetween. The first semiconductor layer, the second semiconductor layer, and the third semiconductor layer contain silicon. The second semiconductor layer and the third semiconductor layer contain the same impurity element. The first insulating layer contains hydrogen, nitrogen, and silicon.

In the above, the first semiconductor layer, the second semiconductor layer, and the third semiconductor layer each preferably contain amorphous silicon.

In the above, the first semiconductor layer, the second semiconductor layer, and the third semiconductor layer each preferably contain polycrystalline silicon. In this case, the second semiconductor layer preferably includes a first portion in contact with the first semiconductor layer and a second portion in contact with the first insulating layer. In addition, a concentration of the impurity element in the first portion is higher than a concentration of the impurity element in the second portion.

In the above, the impurity element is preferably one or more selected from phosphorus, arsenic, boron, and aluminum.

Another embodiment of the present invention is a method for manufacturing a semiconductor device. First, a first conductive layer on an insulating surface and a second semiconductor layer containing an impurity element over the first conductive layer are formed in this order. Then, a first insulating layer is formed to cover the second semiconductor layer. Then, a second conductive layer over the first insulating layer and a third semiconductor layer containing the impurity element over the second conductive layer are formed in this order. Then, part of the third semiconductor layer, part of the second conductive layer, and part of the first insulating layer are etched. Then, an opening reaching the second semiconductor layer is formed. Then, a first semiconductor layer in contact with the third semiconductor layer, the second semiconductor layer, and a side surface of the first insulating layer is formed. Then, a second insulating layer over the first semiconductor layer and a third conductive layer over the second insulating layer are formed in this order. The first semiconductor layer, the second semiconductor layer, and the third semiconductor layer contain silicon.

Another embodiment of the present invention is a method for manufacturing a semiconductor device. First, a first conductive layer on an insulating surface and a second semiconductor layer over the first conductive layer are formed in this order. Then, a first insulating layer is formed to cover the second semiconductor layer. Then, a second conductive layer over the first insulating layer and a third semiconductor layer over the second conductive layer are formed in this order. Then, part of the third semiconductor layer, part of the second conductive layer, and part of the first insulating layer are etched. Then, an opening reaching the second semiconductor layer is formed. Then, an impurity element is added to the third semiconductor layer and a portion of the second semiconductor layer that overlaps with the opening. Then, a first semiconductor layer in contact with the third semiconductor layer, the second semiconductor layer, and a side surface of the first insulating layer is formed. Then, a second insulating layer over the first semiconductor layer and a third conductive layer over the second insulating layer are formed in this order. The first semiconductor layer, the second semiconductor layer, and the third semiconductor layer contain silicon.

In any of the above methods for manufacturing a semiconductor device, one or more selected from phosphorus, arsenic, boron, and aluminum is used as the impurity element.

### MEANS FOR SOLVING THE PROBLEMS

### Effect of the Invention

According to one embodiment of the present invention, a transistor that can be miniaturized can be provided. Alternatively, a transistor having favorable electrical characteristics can be provided. Alternatively, a transistor whose channel length can be reduced can be provided. Alternatively, a transistor that occupies a small area can be provided. Alternatively, a display device that can easily achieve higher resolution can be provided.

According to one embodiment of the present invention, a transistor, a display device, an electronic device, or the like that has a novel structure can be provided. According to one embodiment of the present invention, a transistor, a display device, an electronic device, or the like that has high reliability can be provided. According to one embodiment of the present invention, at least one of problems of the conventional technique can be at least alleviated.

Note that the description of these effects does not preclude the existence of other effects. One embodiment of the present invention does not necessarily have all of these effects. Other effects can be derived from the description of the specification, the drawings, the claims, and the like.

### BRIEF DESCRIPTION OF THE DRAWINGS

FIG. 1A and FIG. 1B are diagrams illustrating a structure example of a semiconductor device.

FIG. 2 is a diagram illustrating a structure example of a semiconductor device.

FIG. 3A is a circuit diagram of a semiconductor device. FIG. 3B and FIG. 3C are diagrams illustrating structure examples of a semiconductor device.

FIG. 4A and FIG. 4B are diagrams illustrating structure examples of a semiconductor device.

FIG. 5A and FIG. 5B are diagrams illustrating structure examples of a semiconductor device.

FIG. 6A to FIG. 6F are diagrams illustrating a method for manufacturing a semiconductor device.

FIG. 7A to FIG. 7E are diagrams illustrating a method for manufacturing a semiconductor device.

FIG. 8A to FIG. 8C are diagrams illustrating a method for manufacturing the semiconductor device.

FIG. 9A to FIG. 9C are diagrams illustrating a method for manufacturing the semiconductor device.

FIG. 10 is a diagram illustrating a structure example of a display device.

FIG. 11 is a diagram illustrating a structure example of a display device.

FIG. 12 is a diagram illustrating a structure example of a display device.

FIG. 13 is a diagram illustrating a structure example of a display device.

FIG. 14 is a diagram illustrating a structure example of a display device.

FIG. 15A to FIG. 15F are diagrams illustrating a method for manufacturing a display device.

FIG. 16A to FIG. 16D are diagrams illustrating examples of electronic devices.

FIG. 17A to FIG. 17F are diagrams illustrating examples of electronic devices.

FIG. 18A to FIG. 18G are diagrams illustrating examples of electronic devices.

### MODE FOR CARRYING OUT THE INVENTION

Embodiments are described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of the embodiments below.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that in this specification and the like, ordinal numbers such as “first” and “second” are used in order to avoid confusion among components and do not limit the number.

In this specification and the like, the term “electrically connected” includes the case where components are connected to each other through an object having any electric action. There is no particular limitation on an “object having any electric function” as long as electric signals can be transmitted and received between components that are connected through the object. Examples of the “object having any electric function” include a switching element such as a transistor, a resistor, a coil, a capacitor, and other elements with any of a variety of functions as well as an electrode and a wiring.

In this specification and the like, the expression “having substantially the same top-view shapes” means that the outlines of stacked layers at least partly overlap with each other. For example, the expression encompasses the case of processing or partly processing an upper layer and a lower layer with the use of the same mask pattern. The expression “having substantially the same top-view shapes” also sometimes encompasses the case where the outlines do not completely overlap with each other; for instance, the outline of the upper layer may be located inward or outward from the outline of the lower layer.

Note that in this specification and the like, the top-view shape of a component means the shape of the outline of the component in a plan view. A plan view means a view to observe the component from a normal direction of a surface where the component is formed or from a normal direction of a surface of a support (e.g., a substrate) where the component is formed.

Note that the expressions indicating directions such as “over” and “under” are basically used to correspond to the directions of drawings. However, in some cases, the direction indicating “over” or “under” in the specification does not correspond to the direction in the drawings for the purpose of description simplicity or the like. For example, when a stacking order (or a formation order) of a stacked body or the like is described, even in the case where a surface on which the stacked body is provided (e.g., a formation surface, a support surface, an adhesion surface, or a planar surface) is positioned above the stacked body in the drawings, the direction and the opposite direction are expressed using “under” and “over”, respectively, in some cases.

In this specification and the like, the term “film” and the term “layer” can be interchanged with each other. For example, in some cases, the term “insulating layer” can be interchanged with the term “insulating film”.

In this specification and the like, a display panel that is one embodiment of a display device has a function of displaying (outputting) an image or the like on (to) a display surface. Therefore, the display panel is one embodiment of an output device.

In this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module, a display module, or simply a display panel or the like in some cases.

Note that in this specification and the like, a touch panel that is one embodiment of a display device has a function of displaying an image or the like on a display surface and a function of a touch sensor capable of detecting the contact, press, approach, or the like of a sensing target such as a finger or a stylus with or to the display surface. Thus, the touch panel is one embodiment of an input/output device.

A touch panel can also be referred to as, for example, a display panel (or a display device) with a touch sensor, or a display panel (or a display device) having a touch sensor function. A touch panel can include a display panel and a touch sensor panel. Alternatively, a touch panel can have a function of a touch sensor in the display panel or on the surface of the display panel.

In this specification and the like, a structure in which a connector or an IC is attached to a substrate of a touch panel is referred to as a touch panel module or a display module, or simply referred to as a touch panel or the like in some cases.

### Embodiment 1

In this embodiment, a semiconductor device of one embodiment of the present invention is described. As examples of the semiconductor device, structure examples of a transistor and examples of a manufacturing method thereof will be described below.

The transistor of one embodiment of the present invention includes a semiconductor layer, a gate insulating layer, a gate electrode, a first electrode, and a second electrode. The first electrode functions as one of a source electrode and a drain electrode, and the second electrode functions as the other.

The second electrode is provided over the first electrode. Between the first electrode and the second electrode, an insulating layer functioning as a spacer is provided. An opening reaching the first electrode is provided in the spacer, and the semiconductor layer is provided in contact with the first electrode, the second electrode, and a side wall (also referred to as a side surface) of the insulating layer in the opening. The gate insulating layer and the gate electrode are provided to cover the semiconductor layer.

The semiconductor layer preferably contains an element semiconductor such as silicon or germanium. In particular, silicon is preferably contained. In that case, each of the first electrode and the second electrode preferably has a stacked-layer structure of a conductive layer and a layer including a semiconductor to which an impurity element is added (an impurity semiconductor layer). The semiconductor layer is provided in contact with the impurity semiconductor layers of the first electrode and the second electrode.

As the impurity element, an element imparting n-type conductivity, such as phosphorus or arsenic, an element imparting p-type conductivity, such as boron or aluminum, or the like can be used.

In the transistor having the above structure, the source electrode and the drain electrode are positioned at different heights, so that the current flowing through the semiconductor layer flows in the height direction. In other words, the channel length direction can be regarded as having a component of the height direction (the vertical direction); accordingly, the transistor of one embodiment of the present invention can be referred to as a vertical field-effect transistor (VFET), a vertical transistor, a vertical-channel transistor, and the like.

In the above transistor, the source electrode, the semiconductor layer, and the drain electrode can be provided to overlap with each other. Thus, the area occupied by the transistor can be significantly smaller than the area occupied by a so-called planar transistor (also referred to as a lateral transistor, a lateral FET (LFET), or the like) in which a semiconductor layer is positioned on a flat plane.

Moreover, since the channel length of the transistor can be precisely controlled by the thickness of the insulating layer, a variation in the channel length can be made extremely reduced as compared with that of a planar transistor. Furthermore, by reducing the thickness of the insulating layer, a transistor with an extremely short channel length can be manufactured. For example, a transistor with a channel length of less than or equal to 2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm and greater than or equal to 5 nm, greater than or equal to 7 nm, or greater than or equal to 10 nm can be manufactured. Thus, it is possible to obtain a transistor with an extremely short channel length that could not be obtained with the use of a conventional light-exposure apparatus for mass production of flat panel displays (the minimum line width: approximately 2 μm or approximately 1.5 μm, for example). Moreover, it is also possible to obtain a transistor with a channel length shorter than 10 nm without using an extremely expensive light-exposure apparatus used in the latest LSI technology.

The display device employing the above-described vertical transistor can reduce the area occupied by transistors as compared to a display device including a conventional lateral transistor, and accordingly achieves a smaller pixel, more multi-functional pixels, and a higher aperture ratio, for example. Accordingly, the display device can achieve higher resolution, higher reliability lower power consumption, and the like than a conventional display device.

More specific structure examples are described below with reference to drawings.

### Structure Example 1

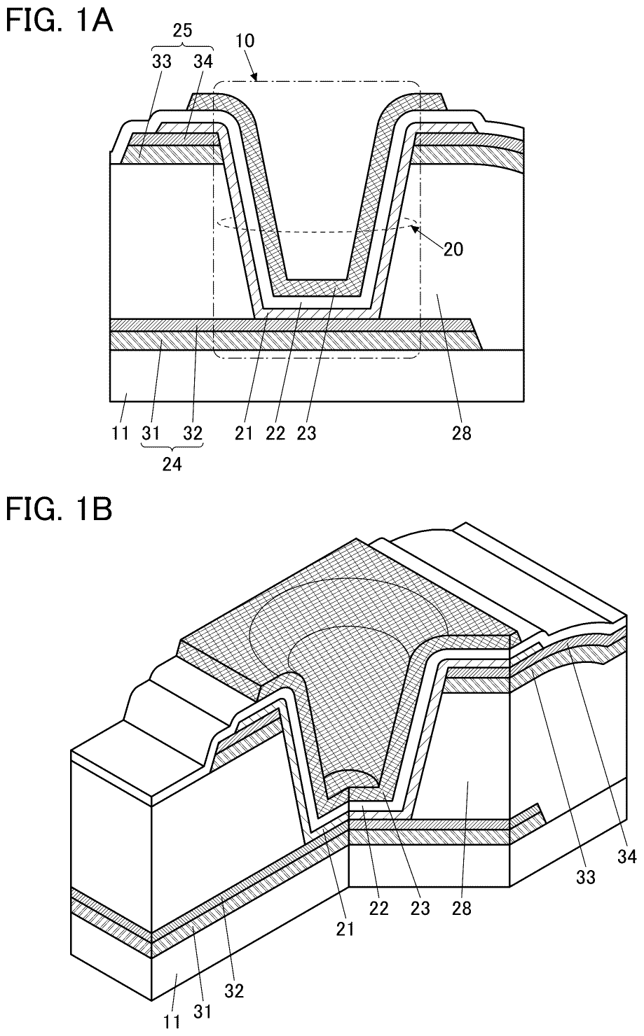

FIG. 1A is a schematic cross-sectional view of a semiconductor device including a transistor 10. FIG. 1B is a schematic perspective view of the semiconductor device. In FIG. 1B, part of the transistor 10 on the front side is cut off for easy viewing of the structure.

The transistor 10 is provided over a substrate 11. The transistor 10 includes a semiconductor layer 21, an insulating layer 22, a conductive layer 23, an electrode layer 24, and an electrode layer 25. Part of the insulating layer 22 functions as a gate insulating layer, and part of the conductive layer 23 functions as a gate electrode. Part of the electrode layer 24 functions as one of a source electrode and a drain electrode, and part of the electrode layer 25 functions as the other of the source electrode and the drain electrode.

The electrode layer 24 has a stacked-layer structure in which a conductive layer 31 and a semiconductor layer 32 are stacked from the substrate 11 side. The electrode layer 25 has a stacked-layer structure in which a conductive layer 33 and a semiconductor layer 34 are stacked from the substrate 11 side. The semiconductor layer 32 and the semiconductor layer 34 contain the same semiconductor material as the semiconductor layer 21. Furthermore, the same impurity element is added to the semiconductor layer 32 and the semiconductor layer 34, and the semiconductor layer 32 and the semiconductor layer 34 exhibit electrical characteristics of an n-type semiconductor or a p-type semiconductor.

The semiconductor layer 21, the semiconductor layer 32, and the semiconductor layer 34 preferably contain an element semiconductor such as silicon or germanium. In particular, silicon is preferably contained. As silicon, amorphous silicon, microcrystalline silicon, polycrystalline silicon, or single crystal silicon can be used; in particular, amorphous silicon, microcrystalline silicon, or polycrystalline silicon, which is possible to be formed over a large-area glass substrate, is preferably used. Accordingly, the transistor 10 can be manufactured with the use of a manufacturing apparatus for a backplane of an existing display; thus, a display device having performance higher than that of the conventional display device can be manufactured without a significant capital investment.

Note that a semiconductor material used for the semiconductor layer is not limited to an element semiconductor, and a compound semiconductor, an oxide semiconductor, an organic semiconductor, or the like can also be used.

In the case where silicon is used as a semiconductor material for each of the semiconductor layer 21, the semiconductor layer 32, and the semiconductor layer 34, examples of an impurity element imparting n-type conductivity include phosphorus and arsenic. On the other hand, examples of an impurity element imparting p-type conductivity include boron and aluminum.

The conductive layer 31 and the conductive layer 33 each preferably contain a conductive material having lower resistance than the semiconductor layer 32 and the semiconductor layer 34. For example, a metal, an alloy, a conductive oxide, or the like can be contained. Thus, part of the conductive layer 31 and part of the conductive layer 33 can be used as wirings. A conductive layer formed by processing the same conductive film as the conductive layer 31 and the conductive layer 33 may be used as a wiring.

The electrode layer 24 is provided over the substrate 11, and an insulating layer 28 is provided to cover the electrode layer 24. The electrode layer 25 is provided over the insulating layer 28. An opening 20 reaching the semiconductor layer 32 of the electrode layer 24 is provided in the electrode layer 25 and the insulating layer 28. For example, it can be said that sidewalls (side surfaces) of the semiconductor layer 34, the conductive layer 33, and the insulating layer 28 that are positioned in the opening 20 overlap with the semiconductor layer 32.

The shape of the opening 20 in a plan view can be typically a circular shape. However, the shape of the opening 20 is not limited to a circular shape and can be a variety of shapes. Besides the circular shape, for example, an elliptical shape or a quadrangular shape with rounded corners can be employed. Alternatively, a regular polygonal shape such as a regular triangular shape, a square shape, or a regular pentagonal shape or a polygonal shape other than the regular polygonal shape may be employed. By employing a depressed polygonal shape in which at least one interior angle is greater than 180°, such as a star polygonal shape, the channel width can be increased. Alternatively, an ellipse, a polygonal shape with rounded corners, a closed curve in which a straight line and a curve are combined, or the like can be employed.

The semiconductor layer 21 is in contact with the top surface of the semiconductor layer 34, the side surfaces of the insulating layer 28, the conductive layer 33, and the semiconductor layer 34 positioned in the opening 20, and the top surface of the semiconductor layer 32 positioned at the bottom of the opening 20. A portion of the semiconductor layer 21 that is in contact with the insulating layer 28 functions as a region where a channel is formed (channel formation region). Note that a portion of the semiconductor layer 21 that is in contact with the semiconductor layer 32 and the vicinity thereof may contain the same impurity element as the semiconductor layer 32. Similarly, a portion of the semiconductor layer 21 that is in contact with the semiconductor layer 34 and the vicinity thereof may contain the same impurity element as the semiconductor layer 34. This is preferable because the contact resistance between the semiconductor layer 21 and the semiconductor layer 32 or the semiconductor layer 34 can be reduced.

Hydrogen is preferably released from the insulating layer 28 by heating. Thus, hydrogen is supplied from the insulating layer 28 to the channel formation region of the semiconductor layer 21 by heat during the process or the like, and the dangling bond in the semiconductor layer 21 can be terminated by the hydrogen, so that the reliability of the transistor 10 can be improved.

As the insulating layer 28, an insulating material such as silicon oxide, silicon oxynitride, silicon nitride oxide, or silicon nitride can be used, for example. As the insulating layer 28, an optimal material can be used depending on a material used for the semiconductor layer 21 and the crystallinity thereof. For example, in the case where amorphous silicon is used for the semiconductor layer 21, silicon nitride oxide or silicon nitride that contains hydrogen is preferably used as the insulating layer 28. In the case where polycrystalline silicon is used for the semiconductor layer 21, silicon oxide or silicon oxynitride that contains hydrogen is preferably used.

The insulating layer 28 can be formed by a film formation method such as a sputtering method or a plasma CVD method. In particular, a film formed by a film formation method such that a plasma CVD method using a gas containing hydrogen or a hydrogen compound as a film formation gas is used can contain a large amount of hydrogen. Thus, a large amount of hydrogen can be supplied to the semiconductor layer 21 by heat during the process or the like, so that the electrical characteristics of the transistor 10 can be stabilized.

Note that the material that can be used for the insulating layer 28 is not limited to the above, and a variety of insulating materials such as an oxide, an oxynitride, a nitride oxide, and a nitride that contain a metal element such as aluminum, hafnium, or yttrium can be used.

Note that in this specification and the like, an oxynitride refers to a material that contains more oxygen than nitrogen. A nitride oxide refers to a material that contains more nitrogen than oxygen.

The insulating layer 22 is provided to cover the insulating layer 28, the electrode layer 25, and the semiconductor layer 21. The conductive layer 23 is provided over the insulating layer 22. Part of the insulating layer 22 and part of the conductive layer 23 each include a portion provided inside the opening 20.

A variety of conductive materials can be used for the conductive layer 23, the conductive layer 31, and the conductive layer 33. For example, one or more of chromium, copper, aluminum, gold, silver, zinc, molybdenum, tantalum, titanium, tungsten, manganese, nickel, iron, cobalt, and niobium or an alloy containing one or more of these metals as its components can be used. Note that the conductive layer 23, the conductive layer 31, and the conductive layer 33 may each have a single-layer structure or a stacked-layer structure.

Part of the insulating layer 22 functions as a gate insulating layer. For example, one or more of silicon oxide, silicon oxynitride, aluminum oxide, aluminum oxynitride, hafnium oxide, hafnium oxynitride, gallium oxide, gallium oxynitride, yttrium oxide, and yttrium oxynitride can be used. In addition, as the insulating layer 22, a nitride insulating film of silicon nitride, silicon nitride oxide, aluminum nitride, or aluminum nitride oxide can also be used. The insulating layer 22 may also have a stacked-layer structure, e.g., a stacked-layer structure including at least one oxide insulating film and at least one nitride insulating film.

As described above, in the transistor 10, the semiconductor layer 21 is in contact with the side surface of the insulating layer 28 and includes a portion functioning as a channel formation region. Here, it can be said that the insulating layer 22 includes a portion facing the side surface of the insulating layer 28 with the semiconductor layer 21 therebetween inside the opening 20. It can also be said that the conductive layer 23 includes a portion facing the side surface of the insulating layer 28 with the semiconductor layer 21 and the insulating layer 22 therebetween inside the opening 20. In that case, it can be said that the interface between the semiconductor layer 21 and the insulating layer 22 and the interface between the insulating layer 22 and the conductive layer 23 each include a portion parallel to the side surface of the insulating layer 28.

Note that an insulating layer functioning as a planarization layer, an interlayer insulating layer, or a protective layer may be provided to cover the insulating layer 22 and the conductive layer 23. A conductive layer functioning as a wiring electrically connected to the electrode layer 24, the electrode layer 25, the conductive layer 23, or the like may be provided over the insulating layer. A pixel electrode that is part included in the display element may be provided over the insulating layer. For example, a pixel electrode, an organic layer, a common electrode, and the like included in a light-emitting element may be provided over the insulating layer.

### Modification Examples

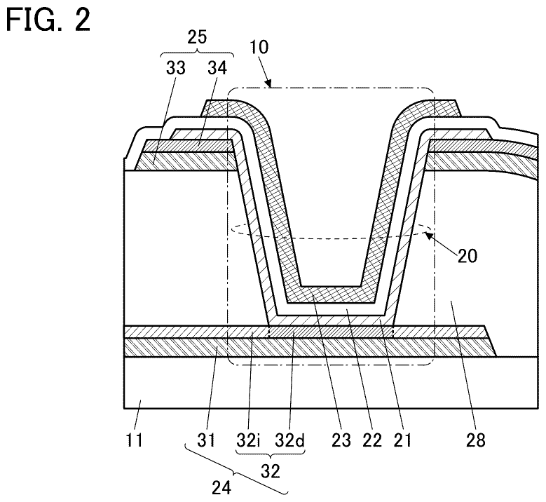

FIG. 2 illustrates a modification example of FIG. 1A. The structure of the transistor 10 illustrated in FIG. 2 is different from that in FIG. 1A mainly in the semiconductor layer 32 that includes a region 32i and a region 32d.

The region 32i is a region of the semiconductor layer 32 that is covered with the insulating layer 28. The region 32d is a region of the semiconductor layer 32 that is positioned at the bottom of the opening 20 and is not covered with the insulating layer 28.

Here, the region 32d is a region to which an impurity element is added, and the region 32i is a region to which an impurity element is not added. Thus, the region 32d in contact with the semiconductor layer 21 has a concentration of the impurity element higher than that of the region 32i in contact with the insulating layer 28. The difference in the concentration of the impurity between the region 32d and the region 32i can be confirmed by, for example, energy dispersive X-ray spectroscopy (EDX) analysis or electron energy-loss spectroscopy (EELS) analysis in a cross section.

After the formation of the opening 20, treatment for adding an impurity element (also referred to as doping treatment) is performed to add the impurity element selectively to the region 32d of the semiconductor layer 32 that is positioned at the bottom of the opening 20, whereby the structure illustrated in FIG. 2 can be manufactured. The details of this process will also be described in a later manufacturing method example.

Here, when one of the semiconductor layer 32 (or the region 32d in FIG. 2) and the semiconductor layer 34 in FIG. 1A contains an impurity element imparting n-type conductivity and the other contains an impurity element imparting p-type conductivity, a p-i-n photodiode can be formed.

### Structure Example 2

Next, a structure in which two kinds of transistors are combined is described. A structure example enabling a CMOS circuit to be formed with an n-channel transistor 10n and a p-channel transistor 10p separately formed is described below. Note that in the following description, the above description is referred to for the contents already described and the description thereof is omitted in some cases.

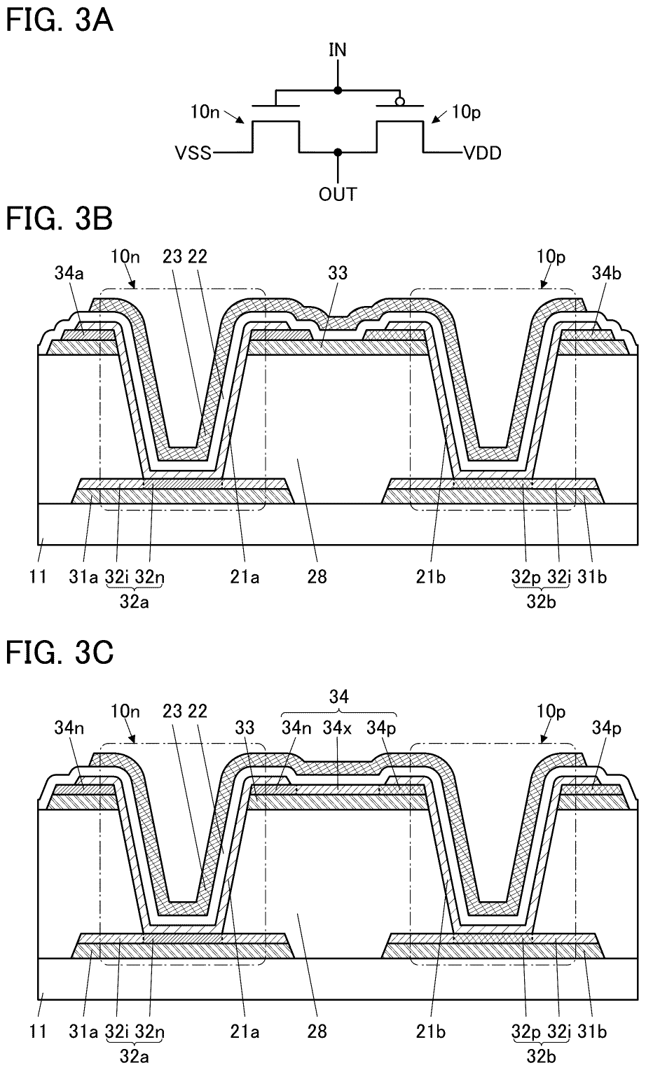

An inverter circuit is one of the simplest CMOS circuits using an n-channel transistor and a p-channel transistor. FIG. 3A illustrates an example of the inverter circuit. The drain of the n-channel transistor 10n and the drain of the p-channel transistor 10p are connected to an output terminal OUT. The gates of the transistors are connected to an input terminal IN. A potential VSS and a potential VDD are supplied to the source of the transistor 10n and the source of the transistor 10p, respectively. The potential VDD is a potential higher than the potential VSS. When the potential VDD is supplied to the input terminal IN, the transistor 10n is turned on and the potential VSS is output to the output terminal OUT. On the other hand, when the potential VSS is supplied to the input terminal IN, the transistor 10p is turned on and the potential VDD is output to the output terminal OUT.

### Structure Example 2-1

FIG. 3B illustrates a schematic cross-sectional view of the transistor 10n and the transistor 10p. The structure in FIG. 3B illustrates an example where the conductive layer 33 and the conductive layer 23 are shared by the transistor 10n and the transistor 10p.

The transistor 10n includes a conductive layer 31a, a semiconductor layer 32a, a semiconductor layer 21a, the conductive layer 33, a semiconductor layer 34a, the insulating layer 22, and the conductive layer 23. The transistor 10p includes a conductive layer 31b, a semiconductor layer 32b, a semiconductor layer 21b, the conductive layer 33, a semiconductor layer 34b, the insulating layer 22, and the conductive layer 23.

The semiconductor layer 32a included in the transistor 10n includes the region 32i and a region 32n. The region 32n and the semiconductor layer 34a contain an impurity element imparting n-type conductivity, such as phosphorus or arsenic. On the other hand, the semiconductor layer 32b included in the transistor 10p includes the region 32i and a region 32p. The region 32p and the semiconductor layer 34b contain an impurity element imparting p-type conductivity, such as boron or aluminum.

The conductive layer 33 is shared between the transistor 10n and the transistor 10p. The semiconductor layer 34a and the semiconductor layer 34b are provided over the conductive layer 33. Although the semiconductor layer 34a and the semiconductor layer 34b are separated from each other over the conductive layer 33 and contain different impurities, they are preferably formed by processing one film. FIG. 3B illustrates an example where the end portion of the semiconductor layer 34a and the end portion of the semiconductor layer 34b are positioned inward from the end portions of the conductive layer 33. At this time, processing of the semiconductor layer 34a and the semiconductor layer 34b and processing of the conductive layer 33 may be performed using different photomasks or a multi-tone mask such as a half-tone mask or a gray-tone mask.

FIG. 3C illustrates an example where the semiconductor layer 34 is shared by the transistor 10n and the transistor 10p. The semiconductor layer 34 includes a region 34n, a region 34p, and a region 34x. Here, the region 34x is a portion positioned between the transistor 10n and the transistor 10p. To the region 34x, an impurity element the same as that in the region 34n may be added, an impurity element the same as that in the region 34p may be added, both of them may be added, or neither of them may be added. That is, the region 34x may have n-type conductivity, p-type conductivity, or no conductivity which is an i-type.

FIG. 3C illustrates an example where the conductive layer 33 and the semiconductor layer 34 have substantially the same top-view shapes. That is, the end portion of the conductive layer 33 and the end portion of the semiconductor layer 34 are substantially aligned with each other. Such a structure enables some processes to be eliminated from the processes needed for the example illustrated in FIG. 3B, so that the manufacturing process can be simplified.

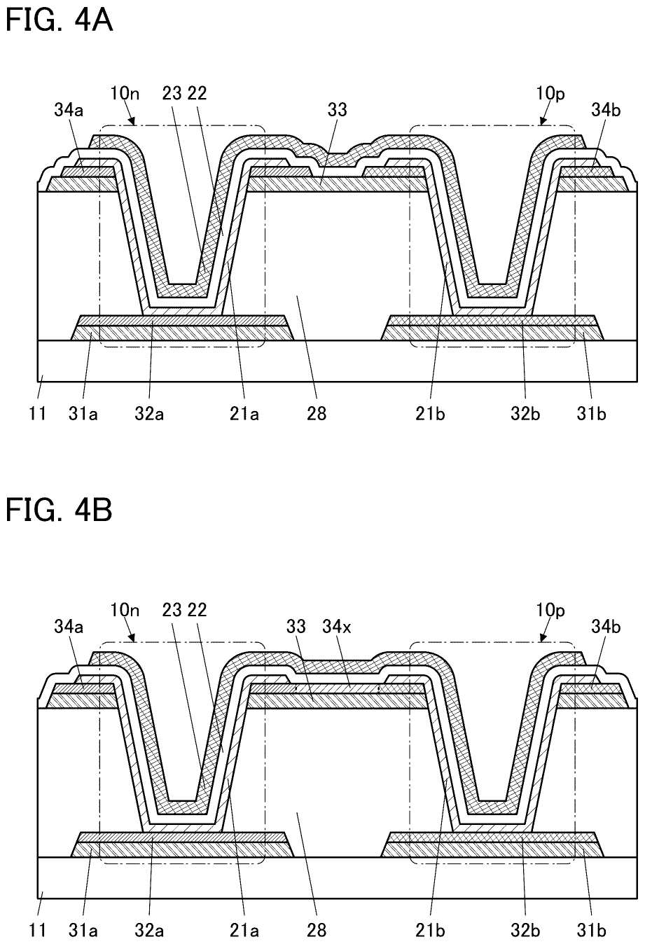

Although FIG. 3B and FIG. 3C illustrate the examples where the semiconductor layer 32a and the semiconductor layer 32b include the region 32n and the region 32p, respectively, at the bottom portion of the opening in the insulating layer 28, an impurity element may be added to a portion overlapping with the insulating layer 28 as illustrated in FIG. 4A and FIG. 4B. That is, the entire semiconductor layer 32a and the entire semiconductor layer 32b may be an n-type impurity semiconductor and a p-type impurity semiconductor, respectively.

### Structure Example 2-2

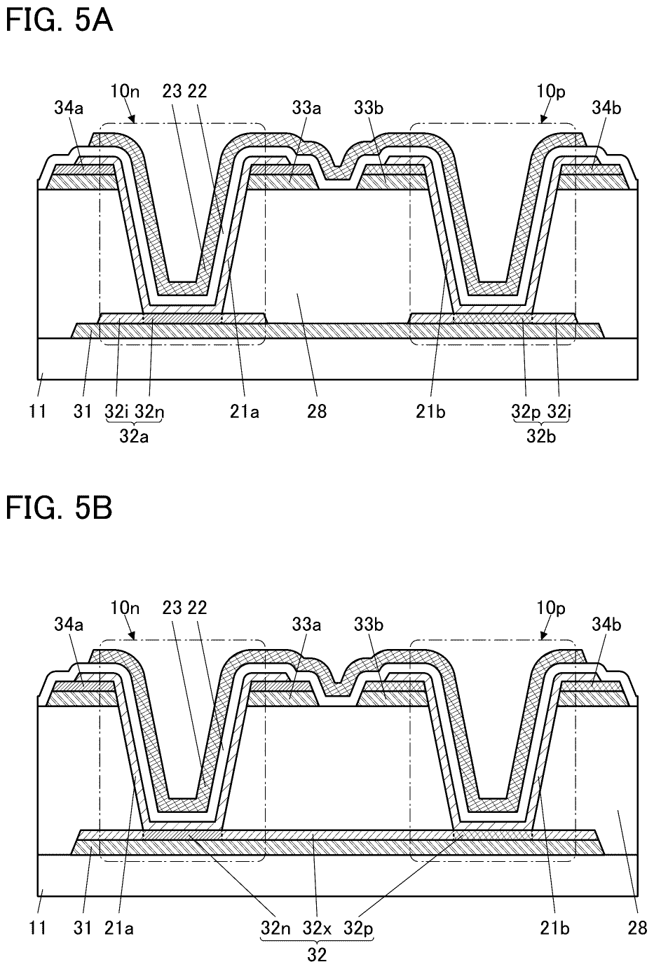

The structure in FIG. 5A illustrates an example where the conductive layer 31 and the conductive layer 23 are shared by the transistor 10n and the transistor 10p.

FIG. 5A illustrates an example where the conductive layer 31 is provided to be shared by the transistor 10n and the transistor 10p, and the semiconductor layer 32 stacked over the conductive layer 31 is separated for each transistor. Specifically, the semiconductor layer 32a included in the transistor 10n includes the region 32i and the region 32n. The semiconductor layer 32b included in the transistor 10p includes the region 32i and the region 32p.

The transistor 10n includes a conductive layer 33a and the semiconductor layer 34a over the insulating layer 28. The transistor 10p includes a conductive layer 33b and the semiconductor layer 34b over the insulating layer 28. The conductive layer 33a and the conductive layer 33b are provided to be apart from each other, and the semiconductor layer 34a and the semiconductor layer 34b are provided to be apart from each other.

FIG. 5B illustrates an example where the semiconductor layer 32 is shared by the transistor 10n and the transistor 10p. The semiconductor layer 32 includes the region 32n, the region 32p, and a region 32x. As in the case of the region 34x, to the region 32x, an impurity element the same as that in the region 32n may be added, an impurity element the same as that in the region 32p may be added, both of them may be added, or neither of them may be added. That is, the region 32x may have n-type conductivity, p-type conductivity, or no conductivity which is an i-type.

The semiconductor layer 32 and the conductive layer 31 are preferably processed using the same photomask, in which case the manufacturing process can be simplified. Thus, as illustrated in FIG. 5B, the semiconductor layer 32 and the conductive layer 31 have substantially the same top-view shapes. Similarly, it is preferable that the top-view shapes of the semiconductor layer 34a and the conductive layer 33a be substantially the same and the top-view shapes of the semiconductor layer 34b and the conductive layer 33b be substantially the same.

Although an example where the transistor 10n and the transistor 10p are formed separately to form a CMOS circuit is described above, each of the transistor 10n and the transistor 10p can be used singly.

Furthermore, a p-i-n photodiode is able to be formed over one substrate when the impurity elements to be added differ from each other. That is, when one of the semiconductor layer 34 and the semiconductor layer 32 contains an impurity element imparting n-type conductivity and the other contains an impurity element imparting p-type conductivity, a p-i-n photodiode can be formed.

### Manufacturing Method Example 1

Next, a method for manufacturing the semiconductor device of one embodiment of the present invention is described. A manufacturing method example for the structure described in Structure example 1 above and illustrated in FIG. 1A, FIG. 1B, and the like is described below.

Thin films included in the semiconductor device (e.g., insulating films, semiconductor films, and conductive films) can be formed by a sputtering method, a chemical vapor deposition (CVD) method, a vacuum evaporation method, a pulsed laser deposition (PLD) method, an atomic layer deposition (ALD) method, or the like. Examples of a CVD method include a plasma-enhanced chemical vapor deposition (PECVD) method and a thermal CVD method. An example of the thermal CVD method is a metal organic chemical vapor deposition (MOCVD: Metal Organic CVD) method.

Thin films included in the semiconductor device (e.g., insulating films, semiconductor films, and conductive films) can be formed by a method such as spin coating, dipping, spray coating, ink-jetting, dispensing, screen printing, offset printing, a doctor knife, slit coating, roll coating, curtain coating, or knife coating.

In processing thin films included in the semiconductor device, a photolithography method or the like can be employed. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Furthermore, instead of the light used for the exposure, an electron beam can also be used. EUV light, X-rays, or an electron beam is preferably used to enable extremely minute processing. Note that a photomask is not needed when light exposure is performed by scanning with a beam such as an electron beam.

For etching of thin films, a dry etching method, a wet etching method, a sandblast method, or the like can be used.

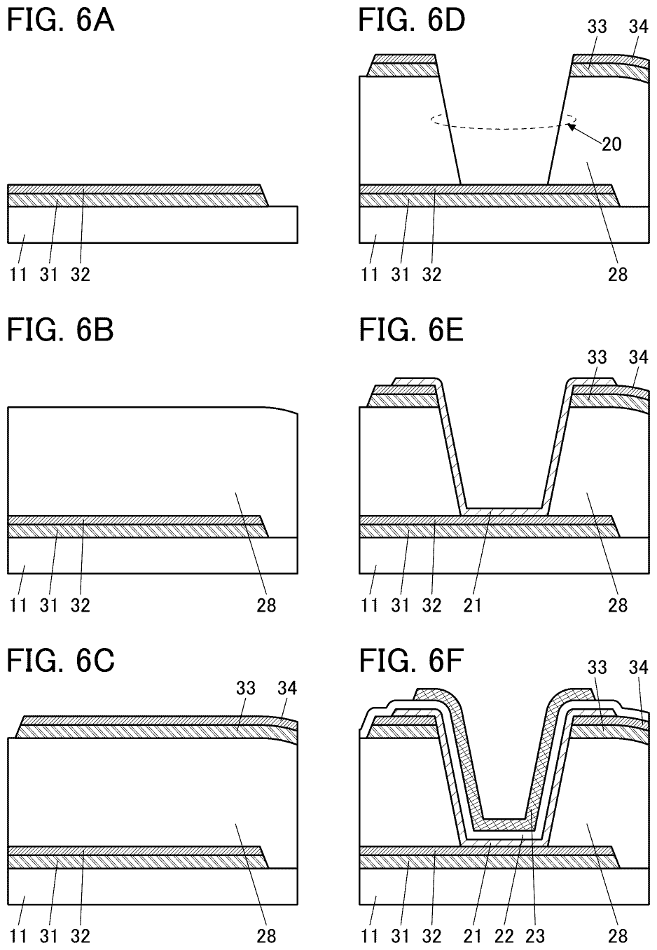

FIG. 6A to FIG. 6F are schematic cross-sectional views corresponding to the processes in a method for manufacturing a semiconductor device described below. Here, an example where an amorphous silicon film or a microcrystalline silicon film is used as the semiconductor film used for the semiconductor layer is described.

First, the substrate 11 is prepared.

As the substrate, a substrate having at least heat resistance high enough to withstand heat treatment performed later can be used. In the case where an insulating substrate is used as the substrate, a glass substrate, a quartz substrate, a sapphire substrate, a ceramics substrate, an organic resin substrate, or the like can be used. Alternatively, a single crystal semiconductor substrate or a polycrystalline semiconductor substrate using silicon, silicon carbide, or the like as a material, a compound semiconductor substrate of silicon germanium, gallium nitride, or the like, or a semiconductor substrate such as an SOI substrate can be used.

Next, a conductive film to be the conductive layer 31 is formed on an insulating surface of the substrate 11. The conductive film can be formed by a sputtering method, for example.

Next, a semiconductor film containing an impurity element to be the semiconductor layer 32 is formed over the conductive film.

In the case of using an amorphous silicon film or a microcrystalline silicon film as the semiconductor film, a plasma CVD method is preferably used. When a mixed gas containing a deposition gas such as SiH₄ or Si₂H₆ and a gas containing an impurity imparting n-type conductivity (e.g., PH₃) or a gas containing an impurity imparting p-type conductivity (e.g., B₂H₆) is used as a film formation gas, an impurity element is added to the semiconductor film so that the semiconductor film exhibiting n-type or p-type conductivity can be formed. In the case of using a germanium film, a deposition gas such as a GeH₄ gas or a Ge₂H₆ gas may be used as a film formation gas.

The crystallinity of the semiconductor film can be controlled by conditions such as pressure, gas flow rate, substrate temperature, and power during the film formation. For example, when the substrate temperature during the film formation is high (e.g., higher than or equal to 100° C. and lower than or equal to 300° C.), a microcrystalline silicon film with high crystallinity that includes crystal grains with a particle diameter of greater than or equal to 1 nm and less than or equal to 100 nm can be formed.

Next, a resist mask is formed over the semiconductor film and unnecessary portions of the semiconductor film and the conductive film are removed by etching, so that the conductive layer 31 and the semiconductor layer 32 are formed over the substrate 11 (FIG. 6A).

Next, the insulating layer 28 is formed to cover the conductive layer 31 and the semiconductor layer 32 (FIG. 6B).

The insulating layer 28 is preferably formed by a plasma CVD method. In particular, a film formed by a plasma CVD method using a gas containing hydrogen or a hydrogen compound as a film formation gas can contain a large amount of hydrogen.

Next, a conductive film to be the conductive layer 33 and a semiconductor film to be the semiconductor layer 34 are formed over the insulating layer 28. After that, part of the conductive film and part of the semiconductor film are removed by etching, so that the conductive layer 33 and the semiconductor layer 34 are formed (FIG. 6C).

The semiconductor film to be the semiconductor layer 34 can be formed by a method similar to that for the semiconductor film to be the semiconductor layer 32.

Next, the opening 20 reaching the semiconductor layer 32 is formed in the semiconductor layer 34, the conductive layer 33, and the insulating layer 28 (FIG. 6D).

The etching of the insulating layer 28 needs to be accurately performed particularly because when a defect such that the opening 20 does not reach the top surface of the semiconductor layer 32 is caused by insufficient etching time or the like in the etching process of the insulating layer 28, the transistor operation is not available. Sufficient overetching is desired for the insulating layer 28 whose thickness is sometimes larger than that of the semiconductor layer 32 or the like in view of variation, but it might eliminate the semiconductor layer 32. The elimination of the semiconductor layer 32 positioned at the bottom of the opening 20 by etching makes normal transistor characteristics unavailable.

Thus, the etching of the insulating layer 28 is preferably performed under conditions where the semiconductor layer 32 is unlikely to be etched so that the semiconductor layer 32 positioned at the bottom portion of the opening 20 is not eliminated by the etching. The insulating layer 28 may be a stacked film in which a plurality of insulating films are stacked, and an insulating film functioning as an etching stopper may be used as the lowermost insulating film (i.e., an insulating film in contact with the semiconductor layer 32).

Next, a semiconductor film is formed over the semiconductor layer 34, the semiconductor layer 32, and the insulating layer 28 and an unnecessary portion is removed by etching, so that the semiconductor layer 21 is formed (FIG. 6E).

The semiconductor film to be the semiconductor layer 21 can be formed by a method similar to that for the semiconductor film. Since the semiconductor film has i-type conductivity here, an impurity element is unnecessary; a gas containing an impurity element is not necessarily introduced into a film formation gas.

Next, the insulating layer 22 is formed to cover the semiconductor layer 21, the conductive layer 33, the semiconductor layer 34, the insulating layer 28, and the like. The insulating layer 22 can be formed by a plasma CVD method, a sputtering method, or the like, for example. It is particularly preferable to employ a plasma CVD method, in which case an insulating layer with a relatively uniform thickness can be formed also inside the opening 20.

Next, a conductive film is formed over the insulating layer 22 and an unnecessary portion is removed by etching, so that the conductive layer 23 is formed (FIG. 6F). The conductive layer 23 can be formed by a method similar to that for the conductive layer 31 or the like.

Through the above processes, the transistor 10 described in Structure example 1 can be manufactured.

### Manufacturing Method Example 2

An example of a method for forming the n-channel transistor 10n and the p-channel transistor 10p separately will be described below. Here, an example where polycrystalline silicon is used as the semiconductor film is described. Note that the description for portions already described in Manufacturing method example 1 is omitted in some cases.

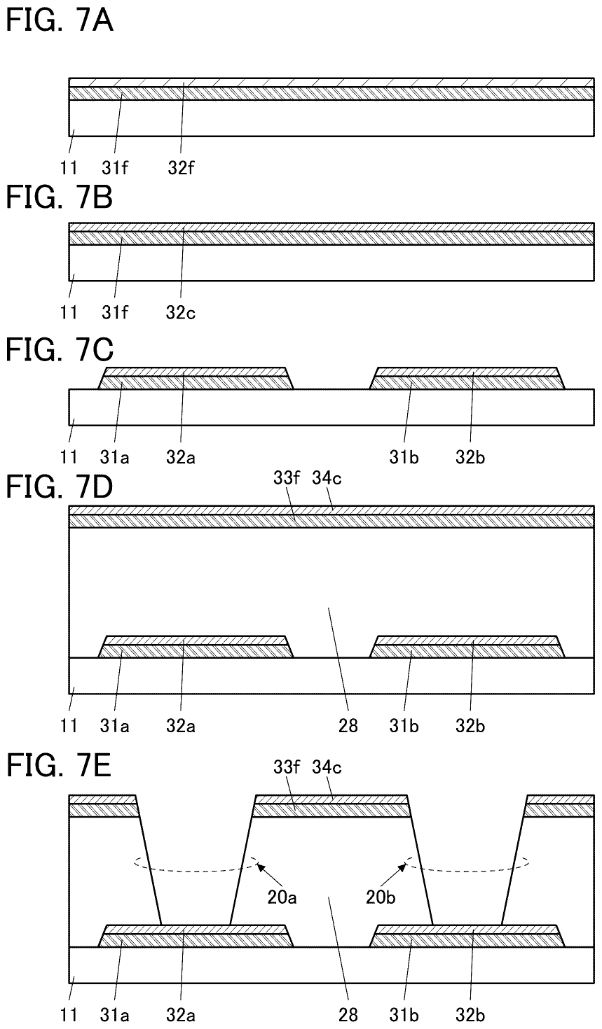

FIG. 7A to FIG. 9C are schematic cross-sectional views corresponding to the processes in a method for manufacturing a semiconductor device described below.

First, a conductive film 31f and a semiconductor film 32f are formed in this order over the substrate 11 (FIG. 7A).

The conductive film 31f is a conductive film to be the conductive layer 31a and the conductive layer 31b later. For the conductive film 31f, a high-melting-point material having heat resistance to heat treatment or the like to be performed later is preferably used. A metal such as tungsten, molybdenum, titanium, tantalum, or chromium or an alloy containing at least one of these metals can be used for the conductive film 31f, for example.

As the semiconductor film 32f, an amorphous silicon film can be used. An amorphous silicon film can be formed by a sputtering method, a plasma CVD method, or the like; it is particularly preferable to employ a plasma CVD method, in which case a dense film can be formed.

Next, the semiconductor film 32f is crystallized to form a semiconductor film 32c containing polycrystalline silicon (FIG. 7B).

Examples of a method for crystallizing the semiconductor film 32f include a laser crystallization method using laser light, a thermal crystallization method using a heat treatment apparatus such as RTA (Rapid Thermal Annealing) or an annealing furnace, and a thermal crystallization method using a metal element promoting crystallization. A combination of two or more of the above crystallization methods may be employed. For example, after a thermal crystallization method using a metal element promoting crystallization, a laser crystallization method may be performed to further increase the crystallinity.

Specific examples of the method for crystallizing the semiconductor film 32f include a method of performing heat treatment (dehydrogenation treatment) for releasing hydrogen contained in the semiconductor film 32f and heat treatment for crystallization successively after coating the semiconductor film 32f with a solution containing nickel, which is a metal element promoting crystallization, first. The dehydrogenation treatment can be performed at 500° C. for one hour, and the subsequent heat treatment for crystallization can be performed at a higher temperature of 550° C. for four hours, for example. After that, laser light irradiation is performed as needed to increase the crystallinity.

A gas laser or a solid-state laser of continuous oscillation or a pulsed oscillation can be used for the laser light. The gas laser includes a YAG laser, a YVO₄ laser, a YLF laser, a YAlO₃ laser, a glass laser, a ruby laser, a Ti: sapphire laser, or the like. The solid laser includes a laser using a crystal such as YAG, YVO₄, TLF, or YAlO₃ doped with Cr, Nd, Er, Ho, Ce, Co, Ti, or Tm.

The crystallization of the amorphous silicon film using a metal element promoting crystallization has an advantage that the crystallization can be performed at a low temperature in a short time and the crystal orientations are aligned with each other but also has a disadvantage that the metal element remains in the polycrystalline silicon film after the crystallization. In view of this, in order to remove the metal element in the polycrystalline silicon film, it is preferable that an amorphous silicon film functioning as a gettering film be formed over the polycrystalline silicon film and the heat treatment be performed. Here, for amorphous silicon film, it is preferable to form a relatively low-dense film by a sputtering method rather than to form a dense film by a plasma CVD method, in which case the gettering effect can be enhanced. The heat treatment is performed to diffuse the metal element into the amorphous silicon film, and then the etching is performed to remove the amorphous silicon film, whereby the concentration of the metal element in the polycrystalline semiconductor film can be reduced.

Note that sometimes there is no problem for the semiconductor film 32c, which is not a semiconductor film used for the semiconductor layer where a channel is formed, to contain a metal element. Thus, the above process of removing the metal element is not necessarily performed for the semiconductor film 32c.

Next, unnecessary portions of the semiconductor film 32c and the conductive film 31f are removed by etching, so that the conductive layer 31a, the conductive layer 31b, the semiconductor layer 32a, and the semiconductor layer 32b are formed (FIG. 7C).

Next, the insulating layer 28, the conductive film 33f, and a semiconductor film 34c are formed in this order (FIG. 7D).

The conductive film 33f is a conductive film to be the conductive layer 33 later. Like the conductive film 31f, the conductive film 33f preferably uses a conductive film having high heat resistance.

The semiconductor film 34c is a semiconductor film containing polycrystalline silicon. The semiconductor film 34c can be formed by crystallizing an amorphous silicon film by a crystallization process similar to that for the semiconductor film 32c.

Next, the opening 20a reaching the semiconductor layer 32a and the opening 20b reaching the semiconductor layer 32b are formed in the semiconductor film 34c, the conductive film 33f, and the insulating layer 28 (FIG. 7E). For the formation of the opening 20a and the opening 20b, Manufacturing method example 1 can be referred to.

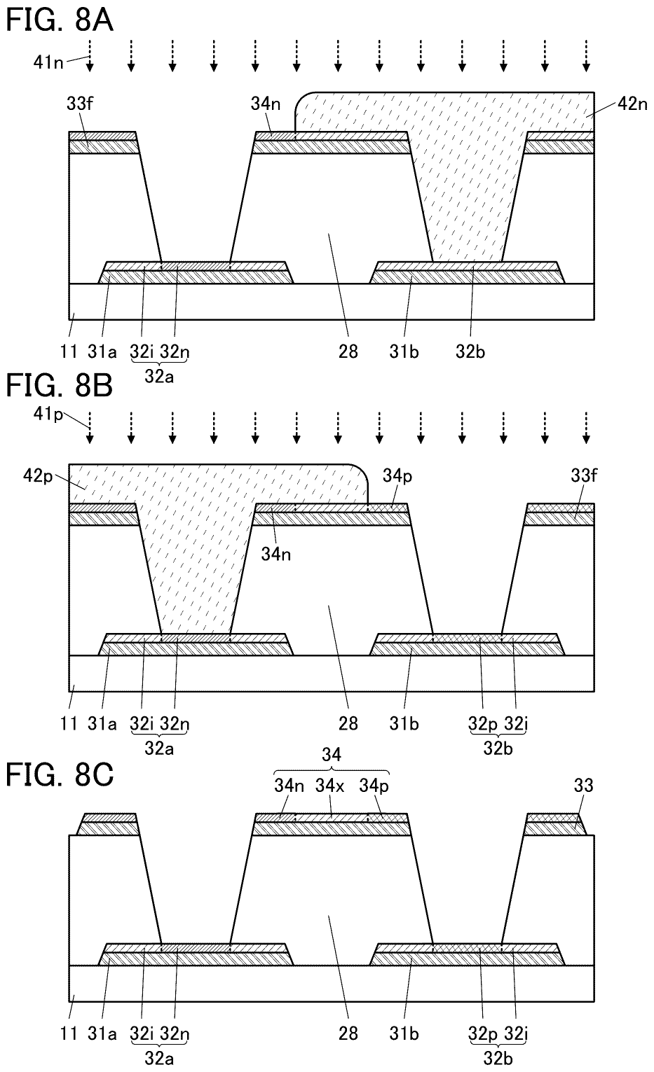

Next, a resist mask 42n is formed to cover the opening 20b and part of the semiconductor film 34c and not to cover the opening 20a and its periphery. After that, the treatment for adding an impurity element 4 In imparting n-type conductivity is performed (FIG. 8A). By the addition treatment, the impurity element 41n is added to each of the semiconductor film 34c positioned in a region not covered with the resist mask 42n and the portion of the semiconductor layer 32a that is positioned at the bottom of the opening 20a. Thus, the region 34n and the region 32n can be formed in the semiconductor film 34c and the semiconductor layer 32a, respectively. After that, the resist mask 42n is removed.

Next, a resist mask 42p is formed to cover the opening 20a and part of the semiconductor film 34c and not to cover the opening 20b and its periphery. After that, the treatment for adding an impurity element 41p imparting p-type conductivity is performed (FIG. 8B). Thus, the region 34p and the region 32p can be formed in the semiconductor film 34c and the semiconductor layer 32b, respectively. After that, the resist mask 42p is removed.

The treatment for adding the impurity element 41n and the impurity element 41p can be performed by an ion doping method, an ion implantation method, or the like. Although the case where the treatment for adding the impurity element 41n is performed before the treatment for adding the impurity element 41p is described here, one embodiment of the present invention is not limited thereto; the treatment for adding the impurity element 41p may be performed first.

After the treatment for adding an impurity element, heat treatment for activating the impurity element may be performed. The heat treatment relieves damage that the semiconductor film 34c, the semiconductor layer 32a, and the semiconductor layer 32b have received from the addition treatment, which results in the recovery of the crystallinity in some cases. The heat treatment can be performed at 550° C. for four hours, for example.

Next, unnecessary portions of the semiconductor film 34c and the conductive film 33f are removed by etching, so that a stacked body of the conductive layer 33 and the semiconductor layer 34 can be formed (FIG. 8C).

At this time, the region 34x is formed between the region 34n and the region 34p in the semiconductor layer 34. Since the region 34x is covered with both the resist mask 42n and the resist mask 42p as illustrated in FIG. 8A and FIG. 8B, the region 34x is a region where no impurity element is added.

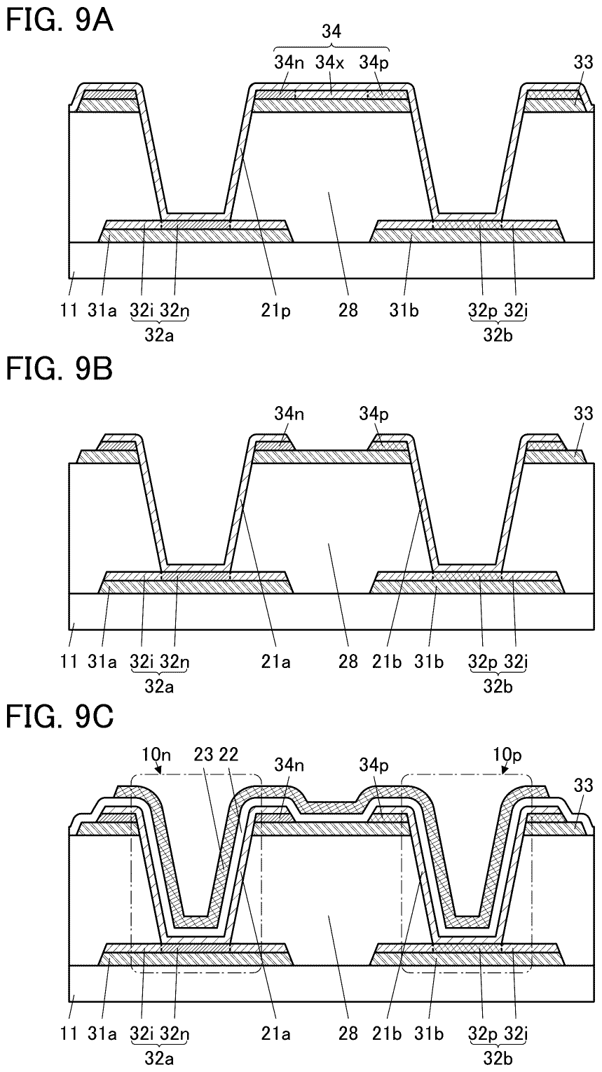

Next, a semiconductor film 21p containing polycrystalline silicon is formed to cover the semiconductor layer 34, the insulating layer 28, the opening 20a, and the opening 20b (FIG. 9A).

The semiconductor film 21p can be formed by crystallizing an amorphous silicon film by a crystallization process similar to that for the semiconductor film 32c. Part of the semiconductor film 21p is used for the semiconductor layer where a channel is formed; thus, in the case of using a metal element promoting crystallization in the crystallization process, the process of removing the metal element is preferably performed.

Next, unnecessary portions of the semiconductor film 21p are removed by etching, so that the semiconductor layer 21a and the semiconductor layer 21b are formed (FIG. 9B).

Since the semiconductor film 21p and the semiconductor layer 34 positioned below the semiconductor film 21p are polycrystalline silicon films, it is sometimes difficult to set a condition with high etching rate selectivity of them at this time. In that case, both the semiconductor film 21p and the semiconductor layer 34 may be etched. FIG. 9B illustrates an example where a portion of the semiconductor layer 34 that is not covered with the semiconductor layer 21a or the semiconductor layer 21b is removed by etching.

Here, after the formation of the semiconductor film 21p or after the etching of the semiconductor film 21p, the treatment for adding an impurity element may be performed to control the threshold voltage of the transistor. For example, the treatment for adding an impurity element imparting p-type conductivity or an impurity element imparting n-type conductivity is performed. The treatment at this time is preferably performed under conditions where the dosage is smaller than that in the above-described treatment for adding the impurity element 41n or the impurity element 41p. In addition, heat treatment for activating the added impurity element may be performed.

Next, the insulating layer 22 is formed to cover the semiconductor layer 21a, the semiconductor layer 21b, the conductive layer 33, the insulating layer 28, and the like. After that, the conductive layer 23 is formed over the insulating layer 22 (FIG. 9C).

Through the above processes, the transistor 10n and the transistor 10p each including a polycrystalline semiconductor can be separately formed.

Note that the structures illustrated in FIG. 3B to FIG. 5B can also be manufactured by changing part of the manufacturing method example described here (e.g., changing a photomask pattern or changing the process order of the treatment for adding impurities).

The above is the description of the manufacturing method example.

At least part of this embodiment can be implemented in combination with any of the other embodiments described in this specification, as appropriate.

### Embodiment 2

In this embodiment, a display device using the semiconductor device of one embodiment of the present invention will be described with reference to the drawings.

The display device of this embodiment can be a high-definition display device or a large-sized display device. Accordingly, the display device of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or notebook personal computer, a monitor of a computer or the like, digital signage, and a large game machine such as a pachinko machine.

The display device of this embodiment can be a high-resolution display device. Accordingly, the display device of this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The semiconductor device of one embodiment of the present invention can be used for a display device or a module including the display device. Examples of the module including the display device include a module in which a connector such as a flexible printed circuit board (hereinafter referred to as an FPC) or a tape carrier package (TCP) is attached to the display device and a module in which the display device is mounted with an integrated circuit (IC) by a chip on glass (COG) method, a chip on film (COF) method, or the like.

### Display device 50A

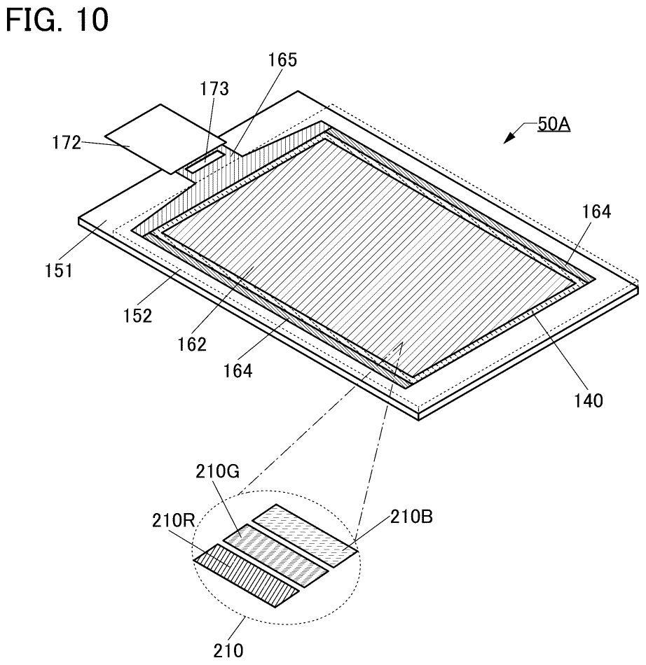

FIG. 10 is a perspective view of a display device 50A

In the display device 50A, a substrate 152 and a substrate 151 are bonded to each other. In FIG. 10, the substrate 152 is indicated by a dashed line.

The display device 50A includes a display portion 162, a connection portion 140, a circuit portion 164, a wiring 165, and the like. FIG. 10 illustrates an example where an IC 173 and an FPC 172 are implemented onto the display device 50A. Thus, the structure illustrated in FIG. 10 can be regarded as a display module including the display device 50A, the IC, and the FPC.

The connection portion 140 is provided outside the display portion 162. The connection portion 140 can be provided along one or more sides of the display portion 162. The number of connection portions 140 may be one or more. FIG. 10 illustrates an example where the connection portion 140 is provided to surround the four sides of the display portion. In the connection portion 140, a common electrode of a display element is electrically connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

The wiring 165 has a function of supplying a signal and power to the display portion 162 and the circuit portion 164. The signal and power are input to the wiring 165 from the outside through the FPC 172 or from the IC 173.

FIG. 10 illustrates an example where the IC 173 is provided on the substrate 151 by a COG method, a COF method, or the like. An IC including one or both of a scan line driver circuit and a signal line driver circuit can be used as the IC 173, for example. Note that the display device 50A and the display module are not necessarily provided with an IC. The IC may be mounted on the FPC by a COF method or the like.

The semiconductor device of one embodiment of the present invention can be used for one or both of the display portion 162 and the circuit portion 164 of the display device 50A, for example. The semiconductor device of one embodiment of the present invention can also be used for the IC 173.

When the semiconductor device of one embodiment of the present invention is used for a pixel circuit of the display device, the area occupied by the pixel circuit can be reduced and the display device can have high resolution, for example. When the semiconductor device of one embodiment of the present invention is used for a driver circuit (e.g., one or both of a gate line driver circuit and a source line driver circuit) of the display device, the area occupied by the driver circuit can be reduced and the display device can have a narrow bezel, for example. Since the semiconductor device of one embodiment of the present invention has favorable electrical characteristics, a display device can have increased reliability by using the semiconductor device.

The display portion 162 of the display device 50A is a region where an image is to be displayed, and includes a plurality of pixels 210 that are periodically arranged. FIG. 10 illustrates an enlarged view of one of the pixels 210.

There is no particular limitation on the arrangement of the pixels in the display device of this embodiment, and any of a variety of arrangements can be employed. Examples of the arrangement of the pixels include stripe arrangement, S-stripe arrangement, matrix arrangement, delta arrangement, Bayer arrangement, and PenTile arrangement.

The pixel 210 illustrated in FIG. 10 includes a subpixel 210R that emits red light, a subpixel 210G that emits green light, and a subpixel 210B that emits blue light.

Any of a variety of elements can be used as the display element, and a liquid crystal element or a light-emitting element can be used, for example. Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (quantum-dot LED) employing a light source and color conversion technology using quantum dot materials may be used.

Examples of a liquid crystal element include a transmissive liquid crystal element, a reflective liquid crystal element, and a transflective liquid crystal element.

Examples of light-emitting elements are self-luminous type light-emitting elements such as an LED (Light Emitting Diode), an OLED (Organic LED), and a semiconductor laser. As the LED, for example, a mini LED, a micro LED, or the like can be used.

Examples of a light-emitting substance contained in the light-emitting element include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (e.g., a quantum dot material).

The light-emitting element can emit infrared, red, green, blue, cyan, magenta, yellow, or white light, for example. When the light-emitting element has a microcavity structure, higher color purity can be achieved.

One of the pair of electrodes of the light-emitting element functions as an anode, and the other electrode functions as a cathode. The display device of one embodiment of the present invention can have any of the following structures: a top-emission structure in which light is emitted in a direction opposite to the substrate where the light-emitting element is formed, a bottom-emission structure in which light is emitted toward the substrate where the light-emitting element is formed, and a dual-emission structure in which light is emitted toward both surfaces.

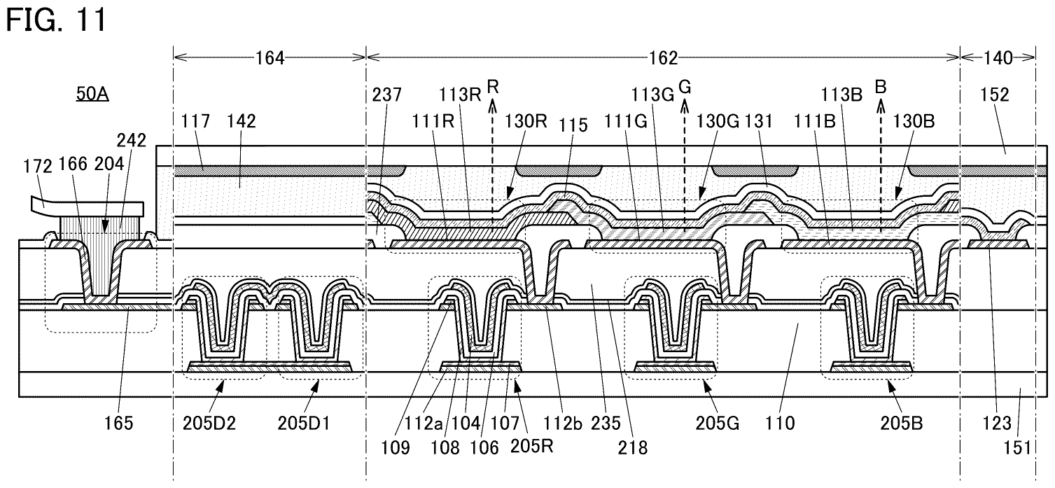

FIG. 11 illustrates an example of cross sections of part of a region including the FPC 172, part of the circuit portion 164, part of the display portion 162, part of the connection portion 140, and part of a region including the end portion of the display device 50A.

The display device 50A illustrated in FIG. 11 includes transistors 205D1, 205D2, 205R, 205G, and 205B, a light-emitting element 130R, a light-emitting element 130G, a light-emitting element 130B, and the like between the substrates 151 and the substrate 152. The light-emitting elements 130R, 130G, and 130B are display elements included in the subpixel 210R that emits red light, the subpixel 210G that emits green light, and the subpixel 210B that emits blue light, respectively.

The display device 50A employs an SBS structure. The SBS structure can optimize materials and structures of light-emitting elements and thus can extend freedom of choice of materials and structures, whereby the luminance and the reliability can be easily improved.

The display device 50A has a top-emission structure. The aperture ratio of pixels in a top-emission structure can be higher than that of pixels in a bottom-emission structure because a transistor and the like can be provided so as to overlap with a light-emitting region of a light-emitting element in the top-emission structure.

All of the transistors 205D1, 205D2, 205R, 205G, and 205B are formed over the substrate 151. These transistors can be manufactured using the same process.

In this embodiment, an example where the transistor of one embodiment of the present invention which includes silicon in the semiconductor is used as each of the transistors 205D1, 205D2, 205R, 205G, and 205B is described. The transistors 205R, 205G, and 205B function as, for example, driving transistors controlling current flowing through the light-emitting elements. Either an n-type transistor or a p-type transistor can be used as the transistors 205R, 205G, and 205B. It is particularly preferable to use the p-type transistor.

In FIG. 11, the transistors 205D1 and 205D2 provided in the circuit portion 164 form part of the driver circuit. Here, an example where the transistors 205D1 and 205D2 form a CMOS circuit is illustrated. For example, it is preferable that one of the transistor 205D1 and the transistor 205D2 be an n-type transistor and the other be a p-type transistor.

Specifically, the transistors 205D1, 205D2, 205R, 205G, and 205B each include a conductive layer 104 functioning as a gate, an insulating layer 106 functioning as a gate insulating layer, a conductive layer 112a and a conductive layer 112b each functioning as a source electrode or a drain electrode, a semiconductor layer 108, a semiconductor layer 107 and a semiconductor layer 109 each functioning as a source region or a drain region, and an insulating layer 110. Here, a plurality of layers obtained by processing one film are shown with the same hatching pattern.

As described above, the display device 50A includes any of the transistors of embodiments of the present invention in both the display portion 162 and the circuit portion 164. When the display portion 162 includes the transistor of one embodiment of the present invention, the pixel size can be reduced and high resolution can be achieved. When the circuit portion 164 includes the transistor of one embodiment of the present invention, the area occupied by the circuit portion 164 can be reduced and a narrower bezel can be achieved. The description in the above embodiment can be referred to for the transistor of one embodiment of the present invention.

Note that the transistor included in the display device of this embodiment is not limited to the transistor of one embodiment of the present invention. For example, the display device of this embodiment may include the transistor of one embodiment of the present invention and a transistor having another structure in combination.

The display device of this embodiment may include one or more of a planar transistor, a staggered transistor, and an inverted staggered transistor. A transistor included in the display device of this embodiment may have a top-gate structure or a bottom-gate structure. Gates may be provided above and below a semiconductor layer where a channel is formed.

A transistor containing silicon in the channel formation region (a Si transistor) is included in the display device of this embodiment. Examples of silicon include single crystal silicon, polycrystalline silicon, and amorphous silicon. In particular, a transistor containing LTPS in its semiconductor layer (hereinafter also referred to as an LTPS transistor) can be used. The LTPS transistor has high field-effect mobility and excellent frequency characteristics. The transistor containing amorphous silicon in the semiconductor layer, which can be uniformly formed over a large-area glass substrate, is excellent in productivity.

The display device of this embodiment may include a transistor using an oxide semiconductor (OS) typified by an In—Ga—Zn oxide (also referred to as IGZO) in the channel formation region (an OS transistor). For example, both a transistor containing silicon in its semiconductor where a channel is formed and a transistor containing an oxide semiconductor may be included in the display device.

The transistor included in the circuit portion 164 and the transistor included in the display portion 162 may have the same structure or different structures. One structure or two or more kinds of structures may be employed for a plurality of transistors included in the circuit portion 164. Similarly, one structure or two or more kinds of structures may be employed for a plurality of transistors included in the display portion 162.

All of the transistors included in the display portion 162 may be Si transistors or OS transistors. Alternatively, some of the transistors included in the display portion 162 may be OS transistors and the others may be Si transistors.

For example, when both an LTPS transistor and an OS transistor are used in the display portion 162, the display device can have low power consumption and high drive capability. Note that a structure in which an LTPS transistor and an OS transistor are used in combination is referred to as LTPO in some cases. As a favorable example, a structure is given in which an OS transistor is used as a transistor functioning as a switch for controlling electrical continuity and discontinuity between wirings and an LTPS transistor is used as a transistor for controlling a current.

For example, one transistor included in the display portion 162 functions as a transistor for controlling a current flowing through the light-emitting element and can also be referred to as a driving transistor. One of a source and a drain of the driving transistor is electrically connected to a pixel electrode of the light-emitting element. An LTPS transistor is preferably used as the driving transistor. In that case, the amount of current flowing through the light-emitting element can be increased in the pixel circuit.

By contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

An insulating layer 218 is provided to cover the transistors 205D1, 205D2, 205R, 205G, and 205B and an insulating layer 235 is provided over the insulating layer 218.

The insulating layer 218 preferably functions as a protective layer of the transistors. A material that does not easily allow diffusion of impurities such as water and hydrogen is preferably used for the insulating layer 218. This is because the insulating layer 218 can function as a barrier layer. Such a structure can effectively inhibit diffusion of impurities into the transistors from the outside and increase the reliability of the display device.

The insulating layer 218 preferably includes one or more inorganic insulating films. Examples of the inorganic insulating film include an oxide insulating film, a nitride insulating film, an oxynitride insulating film, and a nitride oxide insulating film. Specific examples of these inorganic insulating films are as described above.

The insulating layer 235 preferably has a function of a planarization layer, and an organic insulating film is suitably used. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The outermost layer of the insulating layer 235 preferably functions as an etching protective layer. In that case, the formation of a depression in the insulating layer 235 can be inhibited in processing pixel electrodes 111R, 111G, and 111B, for example. Alternatively, a depression may be formed in the insulating layer 235 in processing the pixel electrodes 111R, 111G, and 111B, for example.

The light-emitting elements 130R, 130G, and 130B are provided over the insulating layer 235.

The light-emitting element 130R includes the pixel electrode 111R over the insulating layer 235, an EL layer 113R over the pixel electrode 111R, and a common electrode 115 over the EL layer 113R. The light-emitting element 130R illustrated in FIG. 11 emits red light (R). The EL layer 113R includes a light-emitting layer that emits red light.

In a similar manner, the light-emitting element 130G includes the pixel electrode 111G, an EL layer 113G, and the common electrode 115. The light-emitting element 130G emits green light (G) and the EL layer 113G includes a light-emitting layer that emits green light.

In a similar manner, the light-emitting element 130B includes the pixel electrode 111B, an EL layer 113B, and the common electrode 115. The light-emitting element 130B emits blue light (B) and the EL layer 113B includes a light-emitting layer that emits blue light.

Although the EL layers 113R, 113G, and 113B have the same thickness in FIG. 11, the present invention is not limited thereto. The EL layers 113R, 113G, and 113B may have different thicknesses. For example, the thicknesses of the EL layers 113R, 113G, and 113B are preferably set to match an optical path length that intensifies light emitted from each EL layer. In that case, a microcavity structure is obtained, and the color purity of light emitted from each light-emitting element can be improved

The pixel electrode 111R is electrically connected to the conductive layer 112b included in the transistor 205R through an opening provided in the insulating layer 106, the insulating layer 218, and the insulating layer 235. In a similar manner, the pixel electrode 111G is electrically connected to the conductive layer 112b included in the transistor 205G and the pixel electrode 111B is electrically connected to the conductive layer 112b included in the transistor 205B.

End portions of the pixel electrodes 111R, 111G, and 111B are covered with an insulating layer 237. The insulating layer 237 functions as a partition wall (also referred to as an embankment, a bank, or a spacer). The insulating layer 237 can have a single-layer structure or a stacked-layer structure including one or both of an inorganic insulating material and an organic insulating material. A material that can be used for the insulating layer 218 and a material that can be used for the insulating layer 235 can be used for the insulating layer 237, for example. The insulating layer 237 can electrically isolate the pixel electrode and the common electrode. Furthermore, the insulating layer 237 can electrically isolate light-emitting elements adjacent to each other.

The common electrode 115 is one continuous film shared by the light-emitting elements 130R, 130G, and 130B. The common electrode 115 shared by the light-emitting elements is electrically connected to a conductive layer 123 provided in the connection portion 140. The conductive layer 123 is preferably formed using a conductive layer formed using the same material through the same process as the pixel electrodes 111R, 111G, and 111B.

In the display device of one embodiment of the present invention, a conductive film that transmits visible light is used for the electrode through which light is extracted, which is either the pixel electrode or the common electrode. A conductive film reflecting visible light is preferably used for the electrode through which light is not extracted.

A conductive film that transmits visible light may be used also for the electrode through which light is not extracted. In that case, this electrode is preferably provided between a reflective layer and the EL layer. In other words, light emitted by the EL layer may be reflected by the reflective layer to be extracted from the display device.

As the material of the pair of electrodes of the light-emitting element, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting element preferably employs a microcavity structure. Therefore, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The EL layers 113R, 113G, and 113B are each provided to have an island shape. In FIG. 11, an end portion of the EL layer 113R and an end portion of the EL layer 113G adjacent to each other overlap with each other, an end portion of the EL layer 113G and an end portion of the EL layer 113B adjacent to each other overlap with each other, and an end portion of the EL layer 113R and an end portion of the EL layer 113B adjacent to each other overlap with each other. When island-shaped EL layers are formed using a fine metal mask, end portions of the EL layers adjacent to each other may overlap with each other as illustrated in FIG. 11; however, the present invention is not limited thereto. That is, it is also possible that the EL layers adjacent to each other do not overlap with each other and are apart from each other. It is also possible that the display device includes both a portion where the EL layers adjacent to each other overlap with each other and a portion where the EL layers adjacent to each other do not overlap with each other and are apart from each other.

Each of the EL layers 113R, 113G, and 113B includes at least a light-emitting layer. The light-emitting layer contains one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

The light-emitting layer may contain one or more kinds of organic compounds (e.g., a host material or an assist material) in addition to the light-emitting substance (a guest material). As one or more kinds of organic compounds, one or both of a substance with a good hole-transport property (a hole-transport material) and a substance with a good electron-transport property (an electron-transport material) can be used. As the one or more kinds of organic compounds, a substance with a bipolar property (also referred to as a substance with a good electron-transport property and a good hole-transport property or a bipolar material) or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer containing a substance having a good hole-injection property (a hole-injection layer), a layer containing a hole-transport material (a hole-transport layer), a layer containing a substance having a good electron-blocking property (an electron-blocking layer), a layer containing a substance having a good electron-injection property (an electron-injection layer), a layer containing an electron-transport material (an electron-transport layer), and a layer containing a substance having a good hole-blocking property (a hole-blocking layer). The EL layer may further include one or both of a bipolar material and a TADF material.

Either a low molecular compound or a high molecular compound can be used in the light-emitting element, and an inorganic compound may also be included. Each layer included in the light-emitting element can be formed by any of the following methods: an evaporation method (including a vacuum evaporation method), a transfer method, a printing method, an inkjet method, a coating method, and the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when a voltage is applied between the pair of electrodes. A tandem structure enables a light-emitting element capable of emitting light with high luminance. Furthermore, the amount of current needed for obtaining a predetermined luminance can be smaller in a tandem structure than in a single structure; thus, a tandem structure enables higher reliability. A tandem structure may be referred to as a stack structure.

In the case of using a tandem light-emitting element in FIG. 11, the EL layer 113R preferably includes a plurality of light-emitting units that emit red light, the EL layer 113G preferably includes a plurality of light-emitting units that emit green light, and the EL layer 113B preferably includes a plurality of light-emitting units that emit blue light.

A protective layer 131 is provided over the light-emitting elements 130R, 130G, and 130B. The protective layer 131 and the substrate 152 are bonded to each other with an adhesive layer 142. The substrate 152 is provided with a light-blocking layer 117. A solid sealing structure, a hollow sealing structure, or the like can be employed to seal the light-emitting elements. In FIG. 11, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). In that case, the adhesive layer 142 may be provided not to overlap with the light-emitting element. Alternatively, the space may be filled with a resin other than the frame-shaped adhesive layer 142.

The protective layer 131 is provided at least in the display portion 162, and preferably provided to cover the entire display portion 162. By providing the protective layer 131 over the light-emitting elements 130R, 130G, and 130B, the reliability of the light-emitting elements can be increased. The protective layer 131 is preferably provided to cover not only the display portion 162 but also the connection portion 140 and the circuit portion 164. It is further preferable that the protective layer 131 be provided to extend to the end portion of the display device 50A. Meanwhile, a connection portion 204 has a portion not provided with the protective layer 131 so that the FPC 172 and a conductive layer 166 are electrically connected to each other.

The protective layer 131 may have a single-layer structure or a stacked-layer structure of two or more layers. There is no limitation on the conductivity of the protective layer 131. For the protective layer 131, at least one of an insulating film, a semiconductor film, and a conductive film can be used. The protective layer 131 including an inorganic film can inhibit deterioration of the light-emitting elements by preventing oxidation of the common electrode 115 and inhibiting entry of impurities (e.g., moisture and oxygen) into the light-emitting elements, for example; thus, the reliability of the display device can be improved. For the protective layer 131, an inorganic insulating film such as an oxide insulating film, a nitride insulating film, an oxynitride insulating film, or a nitride oxide insulating film can be used, for example. Specific examples of these inorganic insulating films are as described above. In particular, the protective layer 131 preferably includes a nitride insulating film or a nitride oxide insulating film, and further preferably includes a nitride insulating film.

An inorganic film containing ITO, In—Zn oxide, Ga—Zn oxide, Al—Zn oxide, IGZO, or the like can be used for the protective layer 131. The inorganic film preferably has high resistance, specifically, higher resistance than the common electrode 115. The inorganic film may further contain nitrogen.

When light emitted from the light-emitting element is extracted through the protective layer 131, the protective layer 131 preferably has a good visible-light-transmitting property. For example, ITO, IGZO, and aluminum oxide are preferable because they are inorganic materials having a good visible-light-transmitting property.

The protective layer 131 can be, for example, a stack of an aluminum oxide film and a silicon nitride film over the aluminum oxide film, or a stack of an aluminum oxide film and an IGZO film over the aluminum oxide film. Such a stacked-layer structure can inhibit entry of impurities (e.g., water and oxygen) into the EL layer side.

Furthermore, the protective layer 131 may include an organic film. For example, the protective layer 131 may include both an organic film and an inorganic film. Examples of an organic film that can be used for the protective layer 131 include organic insulating films that can be used for the insulating layer 235.

The connection portion 204 is provided in a region of the substrate 151 not overlapping with the substrate 152. In the connection portion 204, the wiring 165 is electrically connected to the FPC 172 through the conductive layer 166 and a connection layer 242. In this example, the wiring 165 is a single conductive layer obtained by processing the same conductive film as the conductive layer 112b. In this example, the conductive layer 166 is a single conductive layer obtained by processing the same conductive film as the pixel electrodes 111R, 111G, and 111B. On the top surface of the connection portion 204, the conductive layer 166 is exposed. Thus, the connection portion 204 and the FPC 172 can be electrically connected to each other through the connection layer 242.

The display device 50A has a top-emission structure. Light from the light-emitting element is emitted toward the substrate 152. For the substrate 152, a material having a good visible-light-transmitting property is preferably used. The pixel electrodes 111R, 111G, and 111B contain a material that reflects visible light, and the counter electrode (the common electrode 115) contains a material that transmits visible light.

The light-blocking layer 117 is preferably provided on the surface of the substrate 152 on the substrate 151 side. The light-blocking layer 117 can be provided between adjacent light-emitting elements, in the connection portion 140, in the circuit portion 164, and the like.

A coloring layer such as a color filter may be provided on the surface of the substrate 152 on the substrate 151 side or over the protective layer 131. When the color filter is provided so as to overlap with the light-emitting element, the color purity of light emitted from the pixel can be increased.

Moreover, a variety of optical members can be provided on the outer surface of the substrate 152 (the surface opposite to the substrate 151). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 152. For example, a glass layer or a silica layer (SiOₓ layer) is preferably provided as the surface protective layer to inhibit the surface contamination and damage. For the surface protective layer, DLC (diamond-like carbon), aluminum oxide (AlOₓ), a polyester-based material, a polycarbonate-based material, or the like may be used. The surface protective layer is preferably formed using a material having high visible light transmittance. The surface protective layer is preferably formed using a material with high hardness.

For each of the substrate 151 and the substrate 152, glass, quartz, ceramics, sapphire, a resin, a metal, an alloy, a semiconductor, or the like can be used. For the substrate on the side from which light from the light-emitting element is extracted, a material that transmits the light is used. When the substrate 151 and the substrate 152 are formed using a flexible material, the flexibility of the display device can be increased and a flexible display can be achieved. Furthermore, a polarizing plate may be used as at least one of the substrate 151 and the substrate 152.

For each of the substrate 151 and the substrate 152, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used for at least one of the substrate 151 and the substrate 152.

In the case where a circularly polarizing plate overlaps with the display device, a highly optically isotropic substrate is preferably used as the substrate included in the display device. A highly optically isotropic substrate has a low birefringence (in other words, a small amount of birefringence). Examples of the film having high optical isotropy include a triacetyl cellulose (TAC, also referred to as cellulose triacetate) film, a cycloolefin polymer (COP) film, a cycloolefin copolymer (COC) film, and an acrylic film.

As the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet or the like may be used.

As the connection layer 242, an anisotropic conductive film (ACF), an anisotropic conductive paste (ACP), or the like can be used.

### Display Device 50B

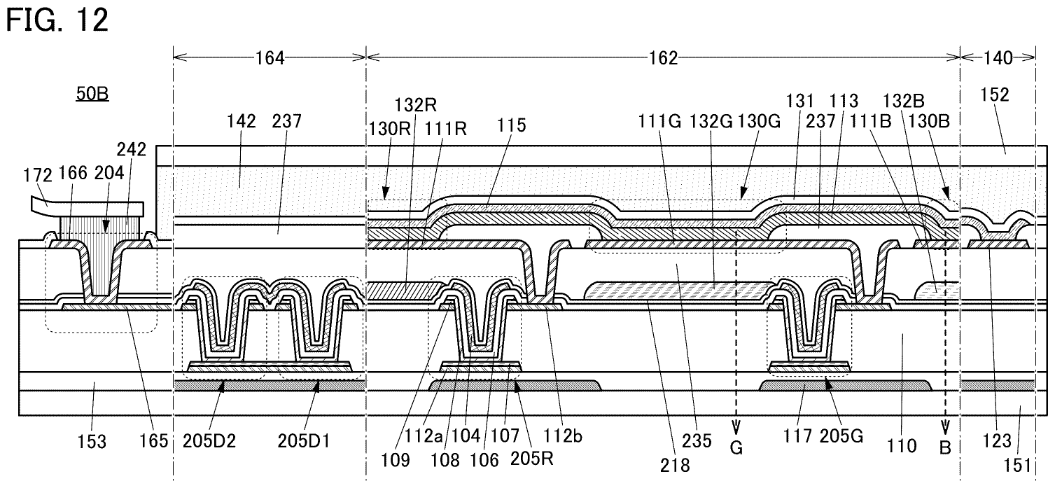

A display device 50B illustrated in FIG. 12 is different from the display device 50A mainly in a bottom-emission display device and in including an EL layer 113 shared by the light-emitting elements and coloring layers (color filters or the like) in the subpixels of different colors. Note that in the following description of display devices, the description of portions similar to those of the above-described display device may be omitted.

Light from the light-emitting element is emitted toward the substrate 151. For the substrate 151, a material having a good visible-light-transmitting property is preferably used. By contrast, there is no limitation on the light-transmitting property of a material used for the substrate 152.

In the display device 50B illustrated in FIG. 12, a transistor 205D, the transistors 205R, 205G, and 205B, the light-emitting elements 130R, 130G, and 130B, a coloring layer 132R transmitting red light, a coloring layer 132G transmitting green light, a coloring layer 132B transmitting blue light, and the like are provided between the substrate 151 and the substrate 152.

The light-emitting element 130R includes the pixel electrode 111R, the EL layer 113 over the pixel electrode 111R, and the common electrode 115 over the EL layer 113. Light emitted from the light-emitting element 130R is extracted as red light to the outside of the display device 50B through the coloring layer 132R.

The light-emitting element 130G includes the pixel electrode 111G, the EL layer 113 over the pixel electrode 111G, and the common electrode 115 over the EL layer 113. Light emitted from the light-emitting element 130G is extracted as green light to the outside of the display device 50B through the coloring layer 132G.

The light-emitting element 130B includes the pixel electrode 111B, the EL layer 113 over the pixel electrode 111B, and the common electrode 115 over the EL layer 113. Light emitted from the light-emitting element 130B is extracted as blue light to the outside of the display device 50B through the coloring layer 132B.

The EL layer 113 and the common electrode 115 are shared between the light-emitting elements 130R, 130G, and 130B. The number of manufacturing processes can be smaller in the case where the EL layer 113 is shared between the subpixels of different colors than the case where the subpixels of different colors include different EL layers.

The light-emitting elements 130R, 130G, and 130B illustrated in FIG. 12 emit white light, for example. When white light emitted from the light-emitting elements 130R, 130G, and 130B passes through the coloring layers 132R, 132G, and 132B, light of desired colors can be obtained.

The light-blocking layer 117 is preferably formed between the substrate 151 and the transistor. FIG. 12 illustrates an example where the light-blocking layers 117 are provided over the substrate 151, an insulating layer 153 is provided over the light-blocking layers 117, and the transistors 205D1, 205D2, the transistor 205R, the transistor 205G, the transistor 205B (not illustrated), and the like are provided over the insulating layer 153. In addition, the coloring layer 132R, the coloring layer 132G, and the coloring layer 132B are provided over the insulating layer 218 and the insulating layer 235 is provided over the coloring layer 132R, the coloring layer 132G, and the coloring layer 132B.

A material having a good visible-light-transmitting property is used for each of the pixel electrodes 111R, 111G, and 111B. A material that reflects visible light is preferably used for the common electrode 115. In the bottom-emission display device, a metal or the like having low resistance can be used for the common electrode 115; thus, a voltage drop due to the resistance of the common electrode 115 can be suppressed and the display quality can be high.

The transistor of one embodiment of the present invention can be miniaturized and the area occupied by the transistor can be reduced, so that the aperture ratio of the pixel can be increased or the pixel size can be reduced in the display device having a bottom-emission structure.

In the case of employing a microcavity structure, the light-emitting elements 130R, 130G, and 130B each emit light with a specific wavelength, which is intensified, in white light emitted from the EL layer 113. Here, even with such a microcavity structure, a light-emitting element including an EL layer that emits white light is referred to as a white-light-emitting element.

In the light-emitting element that emits white light, two or more light-emitting layers are preferably included. When two light-emitting layers are used to obtain white light, two light-emitting layers that emit light of complementary colors are selected. For example, when the emission colors of the first light-emitting layer and the second light-emitting layer are made complementary, the light-emitting element can be configured to emit white light as a whole. In the case where three or more light-emitting layers are used to obtain white light, the light-emitting element is configured to emit white light as a whole by combining emission colors of the three or more light-emitting layers.

For example, the EL layer 113 preferably includes a light-emitting layer containing a light-emitting substance that emits blue light and a light-emitting layer containing a light-emitting substance that emits visible light having a longer wavelength than blue light. The EL layer 113 preferably includes a light-emitting layer that emits yellow light and a light-emitting layer that emits blue light, for example. Alternatively, the EL layer 113 preferably includes a light-emitting layer that emits red light, a light-emitting layer that emits green light, and a light-emitting layer that emits blue light, for example.

A light-emitting element that emits white light preferably has a tandem structure. Specific examples include a two-unit tandem structure including a light-emitting unit that emits yellow light and a light-emitting unit that emits blue light; a two-unit tandem structure including a light-emitting unit that emits red light and green light and a light-emitting unit that emits blue light; a three-unit tandem structure in which a light-emitting unit that emits blue light, a light-emitting unit that emits yellow, yellow-green, or green light, and a light-emitting unit that emits blue light are stacked in this order; and a three-unit tandem structure in which a light-emitting unit that emits blue light, a light-emitting unit that emits yellow, yellow-green, or green light and red light, and a light-emitting unit that emits blue light are stacked in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Alternatively, the light-emitting elements 130R, 130G, and 130B illustrated in FIG. 12 may emit blue light, for example. In this case, the EL layer 113 includes one or more light-emitting layers that emit blue light. In the subpixel 210B that emits blue light, blue light emitted from the light-emitting element 130B can be extracted. In each of the subpixel 210R that emits red light and the subpixel 210G that emits green light, a color conversion layer is provided between the light-emitting element 130R or 130G and the substrate 151 so that blue light emitted from the light-emitting element 130R or 130G is converted into light with a longer wavelength, whereby red light or green light can be extracted. Furthermore, it is preferable that the coloring layer 132R be provided between the color conversion layer and the substrate 151 on an optical path of light emitted by the light-emitting element 130R, and the coloring layer 132G be provided between the color conversion layer and the substrate 151 on an optical path of light emitted by the light-emitting element 130G. In some cases, part of light emitted from the light-emitting element is transmitted through the color conversion layer without being converted. When light transmitted through the color conversion layer is extracted through the coloring layer, light other than light of the intended color can be absorbed by the coloring layer, and color purity of light exhibited by a subpixel can be improved.

### Display Device 50C

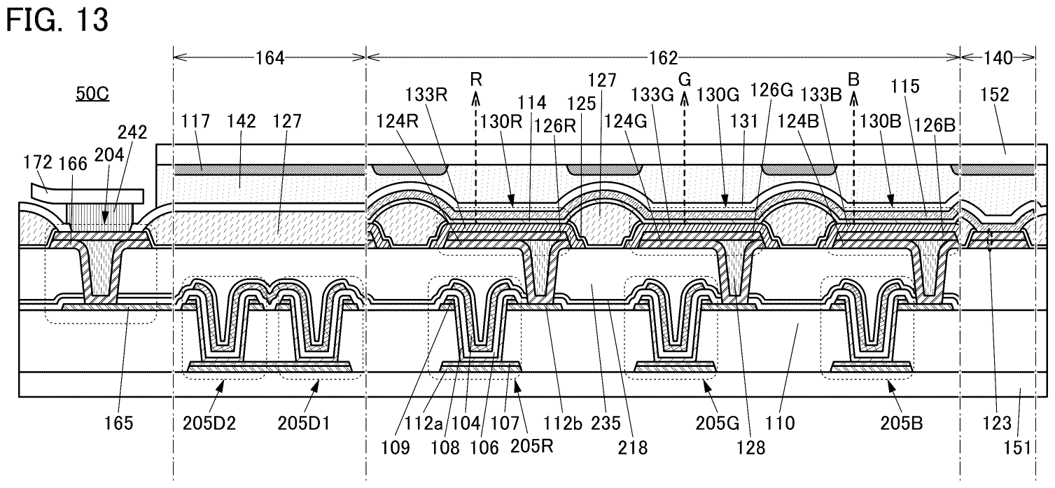

A display device 50C illustrated in FIG. 13 is an example of a display device having an MML (metal maskless) structure. In other words, the display device 50C includes a light-emitting element that is formed without using a fine metal mask. The stacked-layer structure from the substrate 151 to the insulating layer 235 and the stacked-layer structure from the protective layer 131 to the substrate 152 are similar to those in the display device 50A; therefore, description thereof is omitted.

In FIG. 13, the light-emitting elements 130R, 130G, and 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 130R illustrated in FIG. 13 emits red light (R). The layer 133R includes a light-emitting layer that emits red light. In the light-emitting element 130R, the layer 133R and the common layer 114 can be collectively referred to as an EL layer. One or both of the conductive layer 124R and the conductive layer 126R can be referred to as a pixel electrode.

In a similar manner, the light-emitting element 130G includes a conductive layer 124G over the insulating layer 235, a conductive layer 126G over the conductive layer 124G, a layer 133G over the conductive layer 126G, the common layer 114 over the layer 133G, and the common electrode 115 over the common layer 114. The light-emitting element 130G illustrated in FIG. 13 emits green light (G). The layer 133G includes a light-emitting layer that emits green light.

In a similar manner, the light-emitting element 130B includes a conductive layer 124B over the insulating layer 235, a conductive layer 126B over the conductive layer 124B, a layer 133B over the conductive layer 126B, the common layer 114 over the layer 133B, and the common electrode 115 over the common layer 114. The light-emitting element 130B illustrated in FIG. 13 emits blue light (B). The layer 133B includes a light-emitting layer that emits blue light.

In this specification and the like, in the EL layers included in the light-emitting elements, the island-shaped layer provided in each light-emitting element is referred to as the layer 133B, the layer 133G, or the layer 133R, and the layer shared by the light-emitting elements is referred to as the common layer 114. Note that in this specification and the like, only the layer 133R, the layer 133G, and the layer 133B are sometimes referred to as island-shaped EL layers, EL layers formed in an island shape, or the like, in which case the common layer 114 is not included in the EL layer.

The layer 133R, the layer 133G, and the layer 133B are isolated from each other. When the EL layer is provided to have an island shape for each light-emitting element, a leakage current between adjacent light-emitting elements can be inhibited. This can prevent crosstalk-induced unintended light emission, so that a display device with extremely high contrast can be obtained.

Although the layers 133R, 133G, and 133B have the same thickness in FIG. 13, the present invention is not limited thereto. The layers 133R, 133G, and 133B may have different thicknesses.

The conductive layer 124R is electrically connected to the conductive layer 112b included in the transistor 205R through an opening provided in the insulating layer 106, the insulating layer 218, and the insulating layer 235. In a similar manner, the conductive layer 124G is electrically connected to the conductive layer 112b included in the transistor 205G and the conductive layer 124B is electrically connected to the conductive layer 112b included in the transistor 205B.

The conductive layers 124R, 124G, and 124B are formed to cover the openings provided in the insulating layer 235. A layer 128 is embedded in each of the depressions of the conductive layers 124R, 124G, and 124B.

The layer 128 has a function of filling the depressions of the conductive layers 124R, 124G, and 124B. The conductive layers 126R, 126G, and 126B electrically connected to the conductive layers 124R, 124G, and 124B, respectively, are provided over the conductive layers 124R, 124G, and 124B and the layer 128. Thus, regions overlapping with the depressions of the conductive layers 124R, 124G, and 124B can also be used as the light-emitting regions, increasing the aperture ratio of the pixels. The conductive layer 124R and the conductive layer 126R each preferably include a conductive layer functioning as a reflective electrode.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although FIG. 13 illustrates an example where the top surface of the layer 128 includes a flat portion, the shape of the layer 128 is not particularly limited. The top surface of the layer 128 may include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

An end portion of the conductive layer 126R may be aligned with an end portion of the conductive layer 124R or may cover the side surface of the end portion of the conductive layer 124R. The end portions of the conductive layer 124R and the conductive layer 126R each preferably have a tapered shape. Specifically, the end portions of the conductive layer 124R and the conductive layer 126R each preferably have a tapered shape with a taper angle less than 90°. In the case where the end portions of the pixel electrodes have a tapered shape, the layer 133R provided along the side surfaces of the pixel electrodes has an inclined portion. When the side surface of the pixel electrode has a tapered shape, coverage with an EL layer provided along the side surface of the pixel electrode can be improved.

Since the conductive layers 124G and 126G and the conductive layers 124B and 126B are similar to the conductive layers 124R and 126R, the detailed description thereof is omitted.

The top surface and side surface of the conductive layer 126R are covered with the layer 133R. Similarly, the top surface and side surface of the conductive layers 126G are covered with the layer 133G, and the top surface and side surface of the conductive layers 126B are covered with the layer 133B. Accordingly, regions provided with the conductive layers 126R, 126G, and 126B can be entirely used as the light-emitting regions of the light-emitting elements 130R, 130G, and 130B, thereby increasing the aperture ratio of the pixels.

The side surface and part of the top surface of each of the layer 133R, the layer 133G, and the layer 133B are covered with insulating layers 125 and 127. The common layer 114 is provided over the layer 133R, the layer 133G, the layer 133B, and the insulating layers 125 and 127, and the common electrode 115 is provided over the common layer 114. The common layer 114 and the common electrode 115 are each a continuous film provided to be shared by a plurality of light-emitting elements.

In FIG. 13, the insulating layer 237 illustrated in FIG. 11 or the like is not provided between the conductive layer 126R and the layer 133R. That is, an insulating layer (also referred to as a partition wall, a bank, a spacer, or the like) in contact with the pixel electrode and covering an upper end portion of the pixel electrode is not provided in the display device 50C. Thus, the interval between adjacent light-emitting elements can be extremely shortened. Accordingly, the display device can have high resolution or high definition. In addition, a mask for forming the insulating layer is not needed, which leads to a reduction in manufacturing cost of the display device.

As described above, the layer 133R, the layer 133G, and the layer 133B each include the light-emitting layer. The layer 133R, the layer 133G, and the layer 133B each preferably include the light-emitting layer and a carrier-transport layer (an electron-transport layer or a hole-transport layer) over the light-emitting layer. Alternatively, the layer 133R, the layer 133G, and the layer 133B each preferably include a light-emitting layer and a carrier-blocking layer (a hole-blocking layer or an electron-blocking layer) over the light-emitting layer. Alternatively, the layer 133R, the layer 133G, and the layer 133B each preferably include a light-emitting layer, a carrier-blocking layer over the light-emitting layer, and a carrier-transport layer over the carrier-blocking layer. Since surfaces of the layer 133R, the layer 133G, and the layer 133B are exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 114 includes, for example, an electron-injection layer or a hole-injection layer. Alternatively, the common layer 114 may be a stack of an electron-transport layer and an electron-injection layer, or may be a stack of a hole-transport layer and a hole-injection layer. The common layer 114 is shared by the light-emitting elements 130R, 130G, and 130B.

The side surfaces of the layer 133R, the layer 133G, and the layer 133B are each covered with the insulating layer 125. The insulating layer 127 covers the side surfaces of the layer 133R, the layer 133G, and the layer 133B with the insulating layer 125 therebetween.

The side surface and part of the top surface of each of the layer 133R, the layer 133G, and the layer 133B are covered with at least one of the insulating layer 125 and the insulating layer 127, so that the common layer 114 (or the common electrode 115) can be inhibited from being in contact with the side surfaces of the pixel electrodes and the layers 133R, 133G, and 133B, leading to inhibition of a short circuit of the light-emitting elements. Thus, the reliability of the light-emitting element can be increased.

The insulating layer 125 is preferably in contact with the side surfaces of the layer 133R, the layer 133G, and the layer 133B. The insulating layer 125 in contact with the layer 133R, the layer 133G, and the layer 133B can prevent film separation of the layer 133R, the layer 133G, and the layer 133B, whereby the reliability of the light-emitting element can be increased.

The insulating layer 127 is provided over the insulating layer 125 to fill a depression of the insulating layer 125. The insulating layer 127 preferably covers at least part of the side surface of the insulating layer 125.

The insulating layers 125 and the insulating layer 127 can fill a gap between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 114 and the common electrode 115 are provided over the layer 133R, the layer 133G, the layer 133B, the insulating layer 125, and the insulating layer 127. Before the insulating layer 125 and the insulating layer 127 are provided, a step is generated due to a level difference between a region where the pixel electrode and the island-shaped EL layer are provided and a region where neither the pixel electrode nor the island-shaped EL layer is provided (a region between the light-emitting elements). In the display device of one embodiment of the present invention, the step can be eliminated with the insulating layer 125 and the insulating layer 127, and the coverage with the common layer 114 and the common electrode 115 can be improved. Thus, poor connection caused by step disconnection can be inhibited. In addition, an increase in electric resistance, which is caused by local thinning of the common electrode 115 due to the step, can be inhibited.

The top surface of the insulating layer 127 preferably has a shape with high flatness. The top surface of the insulating layer 127 may include at least one of a flat surface, a convex surface, and a concave surface. For example, the top surface of the insulating layer 127 preferably has a smooth convex shape with high flatness.

The insulating layer 125 can be formed using an inorganic material. For the insulating layer 125, an inorganic insulating film such as an oxide insulating film, a nitride insulating film, an oxynitride insulating film, or a nitride oxide insulating film can be used, for example. Specific examples of these inorganic insulating films are as described above. The insulating layer 125 may have a single-layer structure or a stacked-layer structure. In particular, aluminum oxide is preferably used because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film is formed by an ALD method as the insulating layer 125, the insulating layer 125 can have few pinholes and an excellent function of protecting the EL layer. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. The insulating layer 125 preferably has a function of inhibiting diffusion of at least one of water and oxygen. Alternatively, the insulating layer 125 preferably has a function of capturing or fixing (also referred to as gettering) at least one of water and oxygen.

Note that in this specification and the like, a barrier insulating layer refers to an insulating layer having a barrier property. A barrier property in this specification and the like refers to a function of inhibiting diffusion of a targeted substance (also referred to as having low permeability). Alternatively, a barrier property refers to a function of capturing or fixing (also referred to as gettering) a targeted substance.

When the insulating layer 125 has a function of the barrier insulating layer or a gettering function, entry of impurities (typically, at least one of water and oxygen) that would be diffused into the light-emitting elements from the outside can be inhibited. With this structure, a highly reliable light-emitting element and a highly reliable display device can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, the insulating layer 125 preferably has a sufficiently low hydrogen concentration or a sufficiently low carbon concentration, and further preferably has both a sufficiently low hydrogen concentration and a sufficiently low carbon concentration.

The insulating layer 127 provided over the insulating layer 125 has a function of filling large unevenness of the insulating layer 125, which is formed between the adjacent light-emitting elements. In other words, the insulating layer 127 has an effect of improving the planarity of the formation surface of the common electrode 115.

As the insulating layer 127, an insulating layer containing an organic material can be favorably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic polymer in a broad sense in some cases.

Alternatively, the insulating layer 127 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. The insulating layer 127 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used as the photosensitive organic resin. As the photosensitive organic resin, either a positive-type material or a negative-type material may be used.

The insulating layer 127 may be formed using a material absorbing visible light. When the insulating layer 127 absorbs light emitted from the light-emitting element, light leakage (stray light) from the light-emitting element to the adjacent light-emitting element through the insulating layer 127 can be suppressed. Thus, the display quality of the display device can be improved. Since no polarizing plate is required to improve the display quality of the display device, the weight and thickness of the display device can be reduced.

Examples of the material absorbing visible light include a material containing a pigment of black or any other color, a material containing a dye, a light-absorbing resin material (e.g., polyimide), and a resin material that can be used for color filters (a color filter material). Using a resin material obtained by stacking or mixing color filter materials of two or three or more colors is particularly preferred to enhance the effect of blocking visible light. In particular, mixing color filter materials of three or more colors enables the formation of a black or nearly black resin layer.

### Display Device 50D

Light-emitting elements are used as display elements in the above-described example, whereas the following example below shows a liquid crystal display device where liquid crystal elements are used as display elements.

Any of elements with various structures can be used as the liquid crystal elements included in the display device. Typically, a transmissive liquid crystal element employing a vertical alignment (VA) mode, a fringe field switching (FFS) mode, an in-plane switching (IPS) mode, or the like can be used. Instead of a transmissive liquid crystal element, a reflective liquid crystal element or a transflective liquid crystal element may be used as the liquid crystal element. The display device is preferably a normally black liquid crystal display device.

Examples of the VA mode include a multi-domain vertical alignment (MVA) mode, a patterned vertical alignment (PVA) mode, and an advanced super view (ASV) mode.

As the liquid crystal element, a liquid crystal element employing any of a variety of modes can be used. A liquid crystal element can employ, for example, a TN (Twisted Nematic) mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, a guest-host mode, or the like in addition to a VA mode, an FFS mode, and an IPS mode.

Here, the liquid crystal display device is a display device that controls transmission and non-transmission of light by utilizing polarized light and an optical modulation action of a liquid crystal. The optical modulation action of the liquid crystal is controlled by an electric field applied to the liquid crystal (including a horizontal electric field, a vertical electric field, and an oblique electric field). As a liquid crystal that can be used for the liquid crystal element, a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, an anti-ferroelectric liquid crystal, and the like can be used. These liquid crystal materials exhibit a cholesteric phase, a smectic phase, a cubic phase, a chiral nematic phase, an isotropic phase, a blue phase, or the like depending on conditions. As the liquid crystal material, either a positive liquid crystal or a negative liquid crystal may be used, and an appropriate liquid crystal material can be used depending on the mode or design to be used.

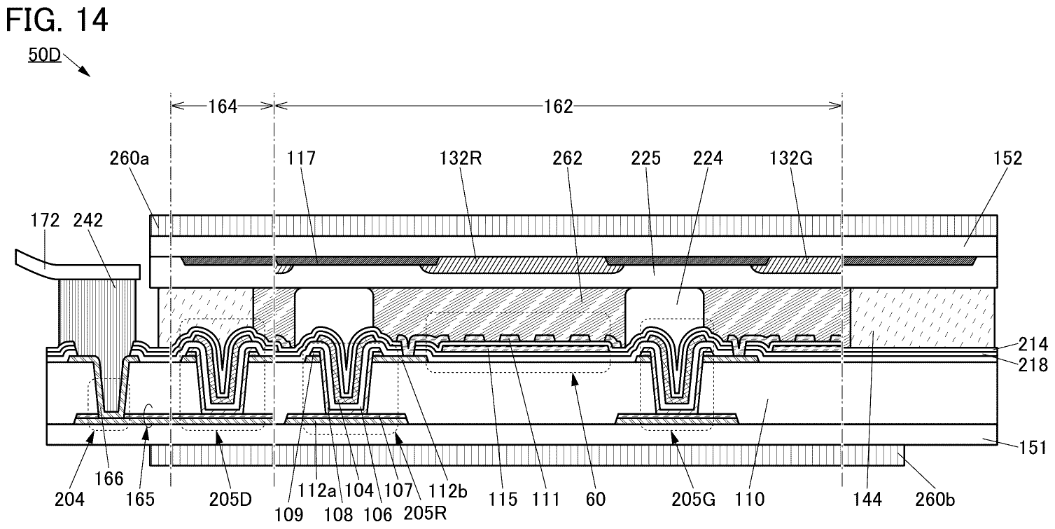

A display device 50D illustrated in FIG. 14 is a liquid crystal display device in an FFS mode.

The substrate 151 and the substrate 152 are bonded to each other with an adhesive layer 144. A liquid crystal 262 is sealed in a region that is surrounded by the substrate 151, the substrate 152, and the adhesive layer 144. A polarizing plate 260a is positioned on the outer surface of the substrate 152, and a polarizing plate 260b is positioned on the outer surface of the substrate 151. Although not illustrated, a backlight can be provided outside the polarizing plate 260a or the polarizing plate 260b.

The substrate 151 is provided with the transistors 205D, 205R, and 205G, the connection portion 204, a spacer 224, and the like. The transistor 205D is provided in the circuit portion 164, and the transistors 205R and 205G are provided in the display portion 162. The conductive layers 112b included in the transistors 205R and 205G are electrically connected to a pixel electrode 111 of a liquid crystal element 60.

The substrate 152 is provided with the coloring layers 132R and 132G, the light-blocking layer 117, an insulating layer 225, and the like.

The transistors 205D, 205R, and 205G each include the conductive layer 112a, the conductive layer 112b, the semiconductor layer 108, the semiconductor layer 107, the semiconductor layer 109, the insulating layer 106, the conductive layer 104, and the like. The conductive layer 112a functions as one of a source electrode and a drain electrode and the conductive layer 112b functions as the other. The semiconductor layer 107 functions as one of a source region and a drain region and the semiconductor layer 109 functions as the other. The conductive layer 104 functions as a gate electrode. Part of the insulating layer 106 functions as a gate insulating layer.

The transistors 205D, 205R, and 205G are covered with the insulating layer 218. The insulating layer 218 has a function of a protective layer of the transistors 205D, 205R, and 205G.

A subpixel included in the display portion 162 includes a transistor, the liquid crystal element 60, and a coloring layer. For example, a subpixel that emits red light includes the transistor 205R, the liquid crystal element 60, and the coloring layer 132R that transmits red light. A subpixel that emits green light includes the transistor 205G, the liquid crystal element 60, and the coloring layer 132G that transmits green light. Similarly, although not illustrated, a subpixel that emits blue light includes a transistor, the liquid crystal element 60, and a coloring layer that transmits blue light.

The liquid crystal element 60 includes the common electrode 115, the pixel electrode 111, and the liquid crystal 262. The common electrode 115 is provided over the insulating layer 218, and an insulating layer 214 is provided over the common electrode 115. The pixel electrode 111 is provided over the insulating layer 214.

The pixel electrode 111 and the common electrode 115 transmit visible light. That is, the liquid crystal element 60 can be a transmissive liquid crystal element. For example, in the case where a backlight is provided on the substrate 151 side, light from the backlight which is polarized by the polarizing plate 260b passes through the substrate 151, the liquid crystal element 60, and the substrate 152, and then reaches the polarizing plate 260a. In this case, optical modulation of the light can be controlled by controlling the alignment of the liquid crystal 262 with a voltage applied between the pixel electrode 111 and the common electrode 115. In other words, the intensity of light emitted through the polarizing plate 260a can be controlled. Light other than one in a particular wavelength region of the incident light is absorbed by the coloring layer, and thus, extracted light is red light, for example.

Here, as the polarizing plate 260a, a linear polarizing plate may be used or a circularly polarizing plate can also be used. An example of a circularly polarizing plate is a stack including a linear polarizing plate and a quarter-wave retardation plate. Reflection of external light can be inhibited with a circularly polarizing plate used as the polarizing plate 260a.

Note that in the case where a circularly polarizing plate is used as the polarizing plate 260a, a circularly polarizing plate or a general linear polarizing plate may be used as the polarizing plate 260b. The cell gap, alignment, driving voltage, and the like of the liquid crystal element used as the liquid crystal element 60 are adjusted in accordance with the kinds of polarizing plates used as the polarizing plate 260a and the polarizing plate 260b so that desirable contrast is obtained.

The connection portion 204 is provided in a region near an end portion of the substrate 151. In the connection portion 204, the wiring 165 is electrically connected to the FPC 172 through the conductive layer 166 and the connection layer 242. The wiring 165 is connected to the wiring 165 through an opening provided in the insulating layer 110. In the structure example illustrated in FIG. 14, the wiring 165 is formed using the same material in the same process as the conductive layer 112a and the semiconductor layer 107, and the conductive layer 166 is formed using the same material in the same process as the conductive layer 112b.

In a plan view, the pixel electrode 111 has a comb-like shape or a shape with a slit. The pixel electrode 111 is provided to overlap with the common electrode 115. There is a portion where the pixel electrode 111 is not provided over the common electrode 115 in a region overlapping with the coloring layer.

Note that in the liquid crystal element 60, both the pixel electrode 111 and the common electrode 115 may have comb-like top-view shapes. Meanwhile, as in the display device 50D, only one of the pixel electrode 111 and the common electrode 115 in the liquid crystal element 60 has a comb-like top-view shape, whereby the pixel electrode 111 and the common electrode 115 partly overlap with each other. This allows capacitance between the pixel electrode 111 and the common electrode 115 to be used as a storage capacitance, and thus another capacitor is not necessarily provided. Accordingly, the aperture ratio of the display device can be increased.

The insulating layer 225 is provided on the substrate 152 side to cover the coloring layers 132R and 132G and the light-blocking layer 117. The insulating layer 225 functions as an overcoat that prevents diffusion of components contained in the coloring layers 132R and 132G and the like into the liquid crystal 262. The insulating layer 225 may have a function of a planarization film. The insulating layer 225 can be formed using a light-transmitting organic resin.

Alignment films for controlling the alignment of the liquid crystal 262 may be provided on surfaces of the pixel electrode 111, the insulating layer 214, the insulating layer 225, and the like which are in contact with the liquid crystal 262.

The above is the description of the structure example of the display device.

### Manufacturing Method Example of Display Device

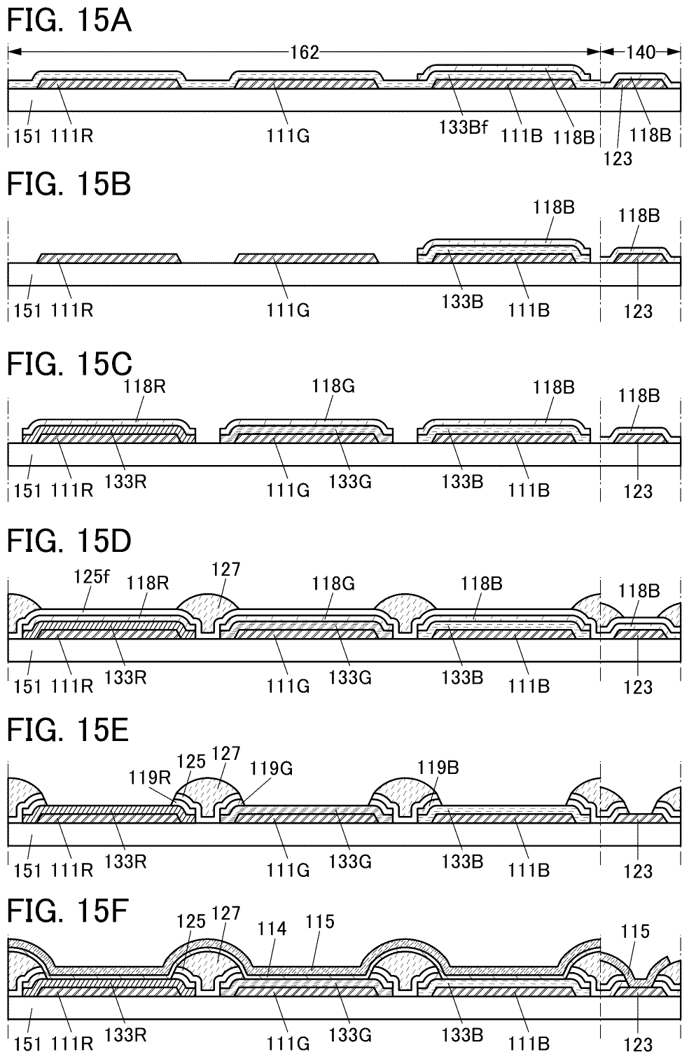

A method for manufacturing a display device having an MML (metal maskless) structure will be described below. Here, processes of manufacturing light-emitting elements without using a fine metal mask will be described in detail. FIG. 15 illustrates cross-sectional views of three light-emitting elements included in the display portion 162 and the connection portion 140 in the processes.

For manufacture of the light-emitting elements, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by a method such as an evaporation method (e.g., a vacuum evaporation method), a coating method (e.g., a dip coating method, a die coating method, a bar coating method, a spin coating method, or a spray coating method), or a printing method (e.g., an inkjet method, a screen printing (stencil) method, an offset printing (planography) method, a flexography (relief printing) method, a gravure printing method, or a micro-contact printing method).

In the method described below for manufacturing the display device, the island-shaped layer (the layer including the light-emitting layer) is formed not by using a fine metal mask but by forming a light-emitting layer on the entire surface and processing the light-emitting layer by a photolithography method. Accordingly, a high-resolution display device or a display device with a high aperture ratio, which has been difficult to be formed so far, can be obtained. Moreover, light-emitting layers can be formed separately for the respective colors, enabling the display device to perform extremely clear display with high contrast and high display quality. Moreover, providing a sacrificial layer over the light-emitting layer can reduce damage to the light-emitting layer in the manufacturing process of the display device, resulting in an increase in reliability of the light-emitting element.

For example, in the case where the display device includes three kinds of light-emitting elements, which are a light-emitting element that emits blue light, a light-emitting element that emits green light, and a light-emitting element that emits red light, three kinds of island-shaped light-emitting layers can be formed by repeating formation of a light-emitting layer and processing by photolithography three times.

First, the pixel electrodes 111R, 111G, and 111B and the conductive layer 123 are formed over the substrate 151 provided with the transistors 205R, 205G, and 205B and the like (not illustrated) (FIG. 15A).

A conductive film to be the pixel electrodes can be formed by a sputtering method or a vacuum evaporation method, for example. A resist mask is formed over the conductive film by a photolithography process, and then the conductive film is processed, whereby the pixel electrodes 111R, 111G, and 111B and the conductive layer 123 can be formed. For the processing of the conductive film, a wet etching method and/or a dry etching method can be used.

Next, a film 133Bf to be the layer 133B later is formed over the pixel electrodes 111R, 111G, and 111B (FIG. 15A). The film 133Bf (to be the layer 133B later) includes a light-emitting layer that emits blue light.

In an example described in this embodiment, an island-shaped EL layer included in the light-emitting element that emits blue light is formed first, and then island-shaped EL layers included in the light-emitting elements that emit light of the other colors are formed.

In the formation process of the island-shaped EL layers, the pixel electrode of the light-emitting element of the color formed second or later is sometimes damaged by the preceding process. In this case, the driving voltage of the light-emitting element of the color formed second or later might be high.

In view of this, in manufacture of the display device of one embodiment of the present invention, it is preferable that an island-shaped EL layer of a light-emitting element that emits light with the shortest wavelength (e.g., the blue-light-emitting element) be formed first. For example, it is preferable that the island-shaped EL layers be formed for the blue-, green-, and red-light-emitting elements in this order or the blue-, red-, and green-light-emitting elements in this order.

This enables the blue-light-emitting element to keep the favorable state of the interface between the pixel electrode and the EL layer and to be inhibited from having an increased driving voltage. In addition, the blue-light-emitting element can have a longer lifetime and higher reliability. Note that the red-light-emitting element and the green-light-emitting element have a smaller increase in driving voltage or the like than the blue-light-emitting element, resulting in a lower driving voltage and higher reliability of the whole display device.

Note that the formation order of the island-shaped EL layers is not limited to the above; for example, the island-shaped EL layers may be formed for the red-, green-, and blue-light-emitting elements in this order.

As illustrated in FIG. 15A, the film 133Bf is not formed over the conductive layer 123. The film 133Bf can be formed only in a desired region using an area mask, for example. Employing a film formation process using an area mask and a processing process using a resist mask enables a light-emitting element to be manufactured by a relatively easy process.

The heat resistance temperature of the compounds contained in the film 133Bf is preferably higher than or equal to 100° C. and lower than or equal to 180° C., further preferably higher than or equal to 120° C. and lower than or equal to 180° C., still further preferably higher than or equal to 140° C. and lower than or equal to 180° C. Thus, the reliability of the light-emitting element can be increased. In addition, the upper limit of the temperature that can be applied in the manufacturing process of the display device can be increased. Therefore, the range of choices of the materials and the manufacturing method of the display device can be widened, thereby improving the manufacturing yield and the reliability.

Examples of the heat resistance temperature include the glass transition point, the softening point, the melting point, the thermal decomposition temperature, and the 5% weight loss temperature, and the lowest one among the temperatures is preferable.

The film 133Bf can be formed by an evaporation method, specifically a vacuum evaporation method, for example. The film 133Bf may be formed by a transfer method, a printing method, an inkjet method, a coating method, or the like.

Next, a sacrificial layer 118B is formed over the film 133Bf and the conductive layer 123 (FIG. 15A). A resist mask is formed over a film to be the sacrificial layer 118B by a photolithography process, and then the film is processed, whereby the sacrificial layer 118B can be formed.

Providing the sacrificial layer 118B over the film 133Bf can reduce damage to the film 133Bf in the manufacturing process of the display device, resulting in an increase in reliability of the light-emitting element.

The sacrificial layer 118B is preferably provided to cover the end portions of the pixel electrodes 111R, 111G, and 111B. Accordingly, the end portion of the layer 133B formed in a later process is positioned outward from the end portion of the pixel electrode 111B. The entire top surface of the pixel electrode 111B can be used as a light-emitting region, so that the aperture ratio of the pixel can be increased. The end portion of the layer 133B might be damaged in a process after the formation of the layer 133B, and thus is preferably positioned outward from the end portion of the pixel electrode 111B, i.e., not used as the light-emitting region. This can suppress a variation in the characteristics of the light-emitting elements and can improve reliability.

When the layer 133B covers the top surface and side surface of the pixel electrode 111B, the processes after the formation of the layer 133B can be performed without exposing the pixel electrode 111B. When the end portion of the pixel electrode 111B is exposed, corrosion might occur in the etching process or the like. When corrosion of the pixel electrode 111B is inhibited, the yield and characteristics of the light-emitting element can be improved.

The sacrificial layer 118B is preferably provided also at a position overlapping with the conductive layer 123. This can inhibit the conductive layer 123 from being damaged during the manufacturing process of the display device.

As the sacrificial layer 118B, a film that is highly resistant to the process conditions for the film 133Bf, specifically, a film having high etching selectivity with respect to the film 133Bf is used.

The sacrificial layer 118B is formed at a temperature lower than the heat resistance temperature of each compound included in the film 133Bf. The typical substrate temperature in the formation of the sacrificial layer 118B is lower than or equal to 200° C., preferably lower than or equal to 150° C., further preferably lower than or equal to 120° C., still further preferably lower than or equal to 100° C., yet still further preferably lower than or equal to 80° C.

The heat resistance temperature of the compound included in the film 133Bf is preferably high, in which case the film formation temperature of the sacrificial layer 118B can be high. For example, the substrate temperature in formation of the sacrificial layer 118B can be higher than or equal to 100° C., higher than or equal to 120° C., or higher than or equal to 140° C. An inorganic insulating film formed at a higher temperature can be denser and have a better barrier property. Therefore, forming the sacrificial layer at such a temperature can further reduce damage to the film 133Bf and improve the reliability of the light-emitting element.

Note that the same can be applied to the film formation temperature of another layer formed over the film 133Bf (e.g., an insulating film 125f).

The sacrificial layer 118B can be formed by a sputtering method, an ALD method (including a thermal ALD method and a PEALD method), a CVD method, or a vacuum evaporation method, for example. Alternatively, the sacrificial layer 118B may be formed by the above-described wet process.

The sacrificial layer 118B (or a layer that is in contact with the film 133Bf in the case where the sacrificial layer 118B has a stacked-layer structure) is preferably formed by a formation method that causes less damage to the film 133Bf. For example, the sacrificial layer 118B is preferably formed by an ALD method or a vacuum evaporation method rather than a sputtering method.

The sacrificial layer 118B can be processed by a wet etching method or a dry etching method. The sacrificial layer 118B is preferably processed by anisotropic etching.

In the case of employing a wet etching method, damage to the film 133Bf in processing of the sacrificial layer 118B can be reduced as compared to the case of employing a dry etching method. In the case of employing a wet etching method, it is preferable to use a developer, a tetramethylammonium hydroxide (TMAH) aqueous solution, dilute hydrofluoric acid, oxalic acid, phosphoric acid, acetic acid, nitric acid, or a mixed solution containing two or more of these acids, for example. In the case of employing a wet etching method, a mixed acid chemical solution containing water, phosphoric acid, diluted hydrofluoric acid, and nitric acid may be used. A chemical solution used for the wet etching treatment may be alkaline or acid.

As the sacrificial layer 118B, one or more of a metal film, an alloy film, a metal oxide film, a semiconductor film, an inorganic insulating film, and an organic insulating film can be used, for example.

For the sacrificial layer 118B, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example.

The sacrificial layer 118B can be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In addition, in place of gallium described above, the element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

For example, a semiconductor material such as silicon or germanium can be used as a material with excellent compatibility with the semiconductor manufacturing process. Alternatively, an oxide or a nitride of the semiconductor material can be used. Alternatively, a non-metallic material such as carbon or a compound thereof can be used. Alternatively, a metal such as titanium, tantalum, tungsten, chromium, or aluminum, or an alloy containing one or more of these metals can be used. Alternatively, an oxide containing the above-described metal, such as titanium oxide or chromium oxide, or a nitride such as titanium nitride, chromium nitride, or tantalum nitride can be used.

For the sacrificial layer 118B, any of a variety of inorganic insulating films that can be used as the protective layer 131 can be used. In particular, an oxide insulating film is preferable because its adhesion to the film 133Bf is higher than that of a nitride insulating film. For example, an inorganic insulating material such as aluminum oxide, hafnium oxide, or silicon oxide can be used for the sacrificial layer 118B. For the sacrificial layer 118B, an aluminum oxide film can be formed by an ALD method, for example. An ALD method is preferably used, in which case damage to a base (in particular, the film 133Bf) can be reduced.

For example, a stacked-layer structure of an inorganic insulating film (e.g., an aluminum oxide film) formed by an ALD method and an inorganic film (e.g., an In—Ga—Zn oxide film, a silicon film, or a tungsten film) formed by a sputtering method can be employed for the sacrificial layer 118B.

Note that the same inorganic insulating film can be used for both the sacrificial layer 118B and the insulating layer 125 that is to be formed later. For example, an aluminum oxide film formed by an ALD method can be used for both the sacrificial layer 118B and the insulating layer 125. For the sacrificial layer 118B and the insulating layer 125, the same film formation condition may be used or different film formation conditions may be used. For example, when the sacrificial layer 118B is formed under conditions similar to those of the insulating layer 125, the sacrificial layer 118B can be an insulating layer having a good barrier property against at least one of water and oxygen. Meanwhile, since the sacrificial layer 118B is a layer a large part or the whole of which is to be removed in a later process, it is preferable that the processing of the sacrificial layer 118B be easy. Therefore, the sacrificial layer 118B is preferably formed with a substrate temperature lower than that for formation of the insulating layer 125.

An organic material may be used for the sacrificial layer 118B. For example, as the organic material, a material that can be dissolved in a solvent chemically stable with respect to at least the uppermost film of the film 133Bf may be used. Specifically, a material that is dissolved in water or alcohol can be suitably used. In forming a film of such a material, it is preferable to apply the material dissolved in a solvent such as water or alcohol by a wet process and then perform heat treatment for evaporating the solvent. At this time, the heat treatment is preferably performed under a reduced-pressure atmosphere, in which case the solvent can be removed at a low temperature in a short time and thermal damage to the film 133Bf can be accordingly reduced.

The sacrificial layer 118B may be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin like perfluoropolymer.

For example, a stacked-layer structure of an organic film (e.g., a PVA film) formed by an evaporation method or the above wet process and an inorganic film (e.g., a silicon nitride film) formed by a sputtering method can be employed for the sacrificial layer 118B.

Note that in the display device of one embodiment of the present invention, part of the sacrificial film remains as the sacrificial layer in some cases.

Then, the film 133Bf is processed using the sacrificial layer 118B as a hard mask, so that the layer 133B is formed (FIG. 15B).

Accordingly, as illustrated in FIG. 15B, the stacked-layer structure of the layer 133B and the sacrificial layer 118B remains over the pixel electrode 111B. In addition, the pixel electrode 111R and the pixel electrode 111G are exposed. In a region corresponding to the connection portion 140, the sacrificial layer 118B remains over the conductive layer 123.

The film 133Bf is preferably processed by anisotropic etching. Anisotropic dry etching is particularly preferable. Alternatively, wet etching may be employed.

After that, process similar to the formation process of the film 133Bf, the formation process of the sacrificial layer 118B, and the formation process of the layer 133B are repeated twice under the condition where at least light-emitting substances are changed, whereby a stacked-layer structure of the layer 133R and a sacrificial layer 118R is formed over the pixel electrode 111R and a stacked-layer structure of the layer 133G and a sacrificial layer 118G is formed over the pixel electrode 111G (FIG. 15C). Specifically, the layer 133R and the layer 133G are formed to include a light-emitting layer that emits red light and a light-emitting layer that emits green light, respectively. The sacrificial layers 118R and 118G can be formed using a material that can be used for the sacrificial layer 118B. The sacrificial layers 118R and 118G may be formed using the same material or different materials.

Note that the side surfaces of the layer 133B, the layer 133G, and the layer 133R are preferably perpendicular or substantially perpendicular to their formation surfaces. For example, the angle between the formation surfaces and these side surfaces is preferably greater than or equal to 60° and less than or equal to 90°.

As described above, the distance between two adjacent layers among the layer 133B, the layer 133G, and the layer 133R formed by a photolithography method can be shortened to less than or equal to 8 μm, less than or equal to 5 μm, less than or equal to 3 μm, less than or equal to 2 μm, or less than or equal to 1 μm. Here, the distance can be determined by, for example, the distance between opposite end portions of two adjacent layers among the layer 133B, the layer 133G, and the layer 133R. When the distance between the island-shaped EL layers is shortened in this manner, a high-resolution display device with a high aperture ratio can be provided.

Next, the insulating film 125f to be the insulating layer 125 later is formed to cover the pixel electrodes, the layer 133B, the layer 133G, and the layer 133R, and the sacrificial layer 118B, the sacrificial layer 118G, and the sacrificial layer 118R, and then the insulating layer 127 is formed over the insulating film 125f (FIG. 15D).

The insulating film 125f is preferably formed to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating film 125f is preferably formed by an ALD method, for example. An ALD method is preferably used, in which case damage during film formation is reduced and a film with good coverage can be formed. As the insulating film 125f, an aluminum oxide film is preferably formed by an ALD method, for example.

Alternatively, the insulating film 125f may be formed by a sputtering method, a CVD method, or a plasma CVD method that provides a higher film formation rate than an ALD method. In this case, a highly reliable display device can be manufactured with high productivity.

For example, the insulating film to be the insulating layer 127 is preferably formed by the aforementioned wet process (e.g., spin coating) using a photosensitive resin composite containing an acrylic resin. After the formation, heat treatment (also referred to as pre-baking) is preferably performed to eliminate a solvent contained in the insulating film. Next, part of the insulating film is irradiated with visible light or ultraviolet rays as light exposure. Next, the region of the insulating film exposed to light is removed by development. Then, heat treatment (also referred to as post-baking) is performed. Accordingly, the insulating layer 127 illustrated in FIG. 15D can be formed. Note that the shape of the insulating layer 127 is not limited to the shape illustrated in FIG. 15D. For example, the top surface of the insulating layer 127 can include one or more of a convex surface, a concave surface, and a flat surface. The insulating layer 127 may cover the side surface of an end portion of at least one of the insulating layer 125, the sacrificial layer 118B, the sacrificial layer 118G, and the sacrificial layer 118R.

Next, as illustrated in FIG. 15E, etching treatment is performed using the insulating layer 127 as a mask to remove portions of the insulating film 125f and the sacrificial layers 118B, 118G, and 118R. Consequently, openings are formed in the sacrificial layers 118B, 118G, and 118R, and the top surfaces of the layer 133G, the layer 133G, the layer 133R, and the conductive layer 123 are exposed. Note that portions of the sacrificial layers 118B, 118G, and 118R may remain in positions overlapping with the insulating layer 127 and the insulating layer 125 (see sacrificial layers 119B, 119G, and 119R).

The etching treatment can be performed by dry etching or wet etching. Note that the insulating film 125f is preferably formed using a material similar to that for the sacrificial layers 118B, 118G, and 118R, in which case etching treatment can be performed collectively.

As described above, by providing the insulating layer 127, the insulating layer 125, the sacrificial layer 118B, the sacrificial layer 118G, and the sacrificial layer 118R, poor connection due to a disconnected portion and an increase in electric resistance due to a locally thinned portion can be inhibited from occurring in the common layer 114 and the common electrode 115 between the light-emitting elements. Thus, the display device of one embodiment of the present invention can have improved display quality.

Next, the common layer 114 and the common electrode 115 are formed in this order over the insulating layer 127, the layer 133B, the layer 133G, and the layer 133R (FIG. 15F).

The common layer 114 can be formed by an evaporation method (including a vacuum evaporation method), a transfer method, a printing method, an inkjet method, a coating method, or the like.

The common electrode 115 can be formed by a sputtering method or a vacuum evaporation method, for example. Alternatively, a film formed by an evaporation method and a film formed by a sputtering method may be stacked.

As described above, in the method for manufacturing the display device of one embodiment of the present invention, the island-shaped layer 133B, the island-shaped layer 133G, and the island-shaped layer 133R are formed not by using a fine metal mask but by forming a film on the entire surface and processing the film; thus, the island-shaped layers can be formed to have a uniform thickness. Consequently, a high-resolution display device or a display device with a high aperture ratio can be obtained. Furthermore, even when the resolution or the aperture ratio is high and the distance between the subpixels is extremely short, the layer 133B, the layer 133G, and the layer 133R can be inhibited from being in contact with each other in the adjacent subpixels. As a result, generation of a leakage current between the subpixels can be inhibited. This can prevent crosstalk-induced unintended light emission, so that a display device with extremely high contrast can be obtained.

The insulating layer 127 having a tapered end portion and being provided between adjacent island-shaped EL layers can prevent step disconnection and a locally thinned portion to be formed in the common electrode 115 at the time of forming the common electrode 115. Thus, poor connection due to a disconnected portion and an increase in electric resistance due to a locally thinned portion can be inhibited from occurring in the common layer 114 and the common electrode 115. Hence, the display device of one embodiment of the present invention achieves both high resolution and high display quality.

The above is the description of the example of the method for manufacturing the display device.

At least part of this embodiment can be implemented in combination with any of the other embodiments described in this specification, as appropriate.

### Embodiment 3

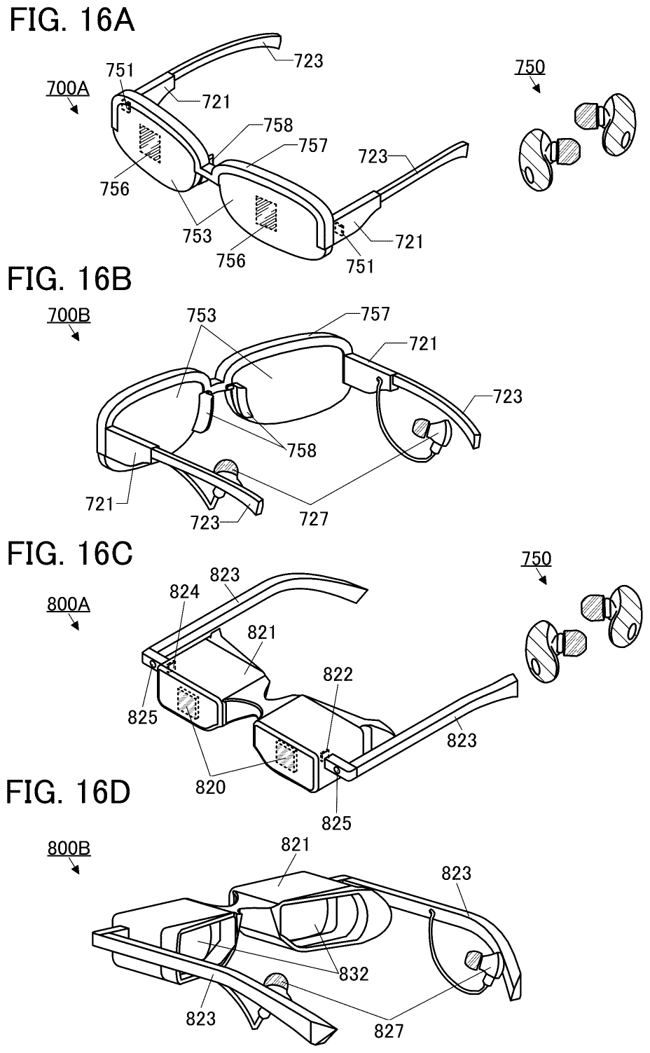

In this embodiment, electronic devices of one embodiment of the present invention will be described with reference to FIG. 16 to FIG. 18.

Electronic devices in this embodiment are each provided with the display device of one embodiment of the present invention in a display portion. The display device of one embodiment of the present invention can be easily increased in resolution and definition. Thus, the display device of one embodiment of the present invention can be used for a display portion of a variety of electronic devices.

A semiconductor device of one embodiment of the present invention can also be applied to any other portion of an electronic device than a display portion. For example, the semiconductor device of one embodiment of the present invention is preferably used for a control portion or the like of an electronic device to enable lower power consumption.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and notebook personal computers, a monitor of a computer and the like, digital signage, and a large game machine such as a pachinko machine.

In particular, the display device of one embodiment of the present invention can have a high resolution, and thus can be favorably used for an electronic device having a relatively small display portion. Examples of such an electronic device include watch-type and bracelet-type information terminal devices (wearable devices) and wearable devices capable of being worn on a head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably 100 ppi or higher, further preferably 300 ppi or higher, still further preferably 500 ppi or higher, yet still further preferably 1000 ppi or higher, yet still further preferably 2000 ppi or higher, yet still further preferably 3000 ppi or higher, yet still further preferably 5000 ppi or higher, yet still further preferably 7000 ppi or higher. The use of the display device having one or both of such high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices will be described with reference to FIG. 16A to FIG. 16D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 16A and an electronic device 700B illustrated in FIG. 16B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic devices are capable of performing ultrahigh-resolution display.

The electronic device 700A and the electronic device 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A and the electronic device 700B are each provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 16C and an electronic device 800B illustrated in FIG. 16D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, the electronic devices are capable of performing ultrahigh-resolution display. Such electronic devices provide a high sense of immersion to the user.

The display portions 820 are positioned inside the housing 821 so as to be seen through the lenses 832. When the pair of display portions 820 display different images, three-dimensional display using parallax can be performed.

Each of the electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. In addition, a mechanism for adjusting focus by changing the distance between the lenses 832 and the display portions 820 is preferably included.

The electronic device 800A or the electronic device 800B can be mounted on the user's head with the wearing portions 823. FIG. 16C and the like illustrate examples where the wearing portion 823 has a shape like a temple of glasses; however, one embodiment of the present invention is not limited thereto. The wearing portion 823 may have any shape with which the user can wear the electronic device, such as a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Note that although an example where the image capturing portion 825 is included is illustrated here, a range sensor that is capable of measuring the distance to an object (hereinafter such a sensor is also referred to as a sensing portion) is provided. In other words, the image capturing portion 825 is one embodiment of the sensing portion. For the sensing portion, an image sensor or a distance image sensor such as LIDAR (Light Detection and Ranging) can be used, for example. By using images obtained by a camera and images obtained by the distance image sensor, more pieces of information can be obtained and a gesture operation with higher accuracy is possible.

The electronic device 800A may include a vibration mechanism that functions as a bone-conduction earphone. For example, at least one of the display portion 820, the housing 821, and the wearing portion 823 can include the vibration mechanism. Thus, without additionally requiring an audio device such as headphones, earphones, or a speaker, the user can enjoy images and sound only by wearing the electronic device 800A.

The electronic device 800A and the electronic device 800B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 16A has a function of transmitting information to the earphones 750 with the wireless communication function. As another example, the electronic device 800A in FIG. 16C has a function of transmitting information to the earphones 750 with the wireless communication function.

The electronic device may include an earphone portion. The electronic device 700B in FIG. 16B includes earphone portions 727. For example, the earphone portion 727 can be connected to the control portion by wire. Part of a wiring that connects the earphone portion 727 and the control portion may be positioned inside the housing 721 or the wearing portion 723.

Similarly, the electronic device 800B in FIG. 16D includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (the electronic device 700A, the electronic device 700B, or the like) and the goggles-type device (the electronic device 800A, the electronic device 800B, or the like) are suitable as the electronic device of one embodiment of the present invention.

The electronic device of one embodiment of the present invention can transmit information to earphones by wire or wirelessly.

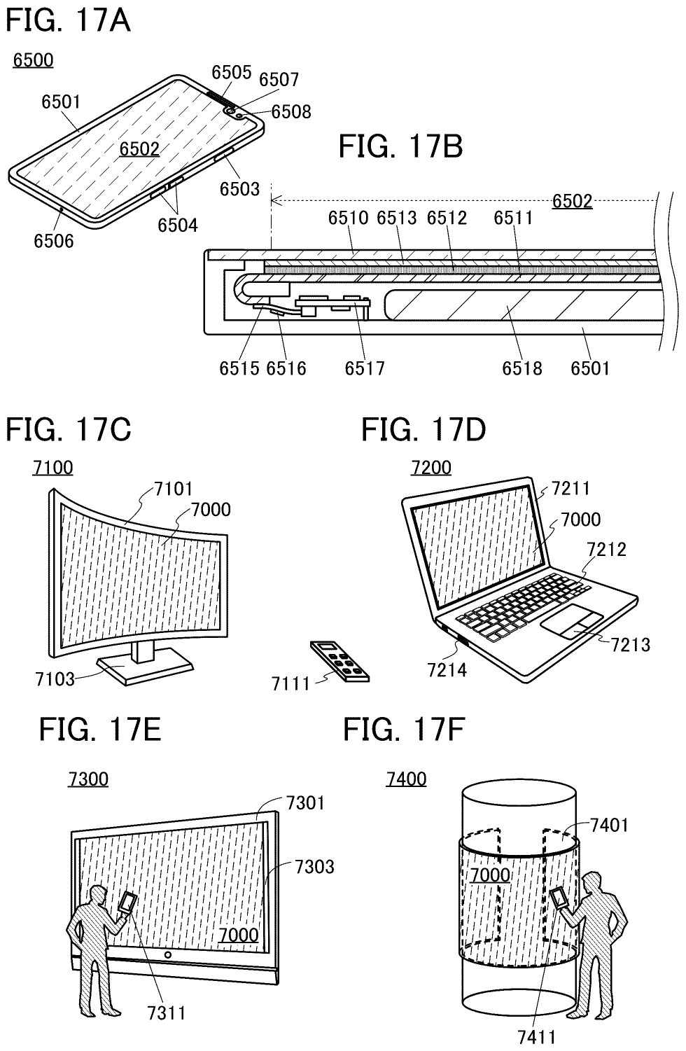

An electronic device 6500 illustrated in FIG. 17A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 17B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. In that case, an extremely lightweight electronic device can be obtained. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be obtained.

FIG. 17C illustrates an example of a television device. In a television device 7100, a display portion 7000 is incorporated in a housing 7101. Here, the housing 7101 is supported by a stand 7103.

The display device of one embodiment of the present invention can be used in the display portion 7000.

Operation of the television device 7100 illustrated in FIG. 17C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 17D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000.

FIG. 17E and FIG. 17F illustrate examples of digital signage.

Digital signage 7300 illustrated in FIG. 17E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 17F illustrates digital signage 7400 attached to a cylindrical pillar 7401. The digital signage 7400 includes the display portion 7000 provided along a curved surface of the pillar 7401.

The display device of one embodiment of the present invention can be used in the display portion 7000 illustrated in each of FIG. 17E and FIG. 17F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 17E and FIG. 17F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

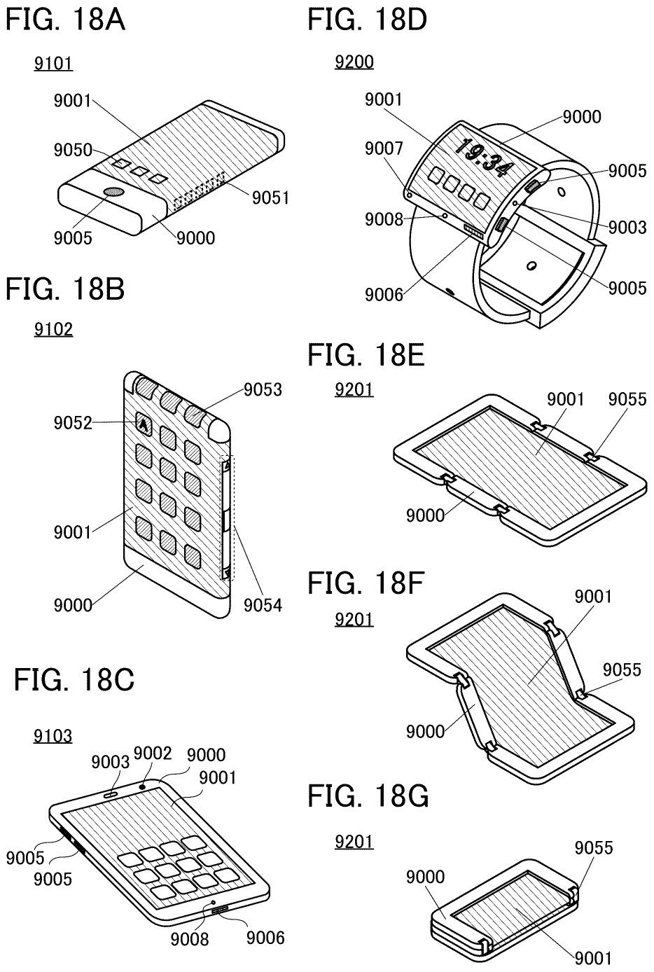

Electronic devices illustrated in FIG. 18A to FIG. 18G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

In FIG. 18A to FIG. 18G, the display device of one embodiment of the present invention can be used in the display portion 9001.

The electronic devices illustrated in FIG. 18A to FIG. 18G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of capturing a still image or a moving image, a function of storing the captured image in a storage medium (an external storage medium or a storage medium incorporated in the camera), a function of displaying the captured image on the display portion, and the like.

The electronic devices in FIG. 18A to FIG. 18G will be described in detail below.

FIG. 18A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 18A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 18B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 18C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 18D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 18E to FIG. 18G are perspective views of a foldable portable information terminal 9201. FIG. 18E is a perspective view illustrating the portable information terminal 9201 that is opened. FIG. 18G is a perspective view illustrating the portable information terminal 9201 that is folded. FIG. 18F is a perspective view illustrating the portable information terminal 9201 that is shifted from one of the states in FIG. 18E and FIG. 18G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

At least part of this embodiment can be implemented in combination with any of the other embodiments described in this specification, as appropriate.

### REFERENCE NUMERALS

10n: transistor, 10p: transistor, 10: transistor, 11: substrate, 20a: opening, 20b: opening, 20: opening, 21a: semiconductor layer, 21b: semiconductor layer, 21p: semiconductor film, 21: semiconductor layer, 22: insulating layer, 23: conductive layer, 24: electrode layer, 25: electrode layer, 28: insulating layer, 31a: conductive layer, 31b: conductive layer, 31f: conductive film, 31: conductive layer, 32a: semiconductor layer, 32b: semiconductor layer, 32c: semiconductor film, 32d: region, 32f: semiconductor film, 32i: region, 32n: region, 32p: region, 32x: region, 32: semiconductor layer, 33a: conductive layer, 33b: conductive layer, 10 33f: conductive film, 33: conductive layer, 34a: semiconductor layer, 34b: semiconductor layer, 34c: semiconductor film, 34n: region, 34p: region, 34x: region, 34: semiconductor layer, 41n: impurity element, 41p: impurity element, 42n: resist mask, 42p: resist mask

1. A semiconductor device comprising:
a first conductive layer, a second conductive layer, a third conductive layer, a first semiconductor layer, a second semiconductor layer, a third semiconductor layer, a first insulating layer, and a second insulating layer,
wherein the second semiconductor layer is provided over the first conductive layer,
wherein the first insulating layer is provided over the second semiconductor layer,
wherein the second conductive layer is provided over the first insulating layer,
wherein the third semiconductor layer is provided over the second conductive layer,
wherein the first insulating layer comprises an opening reaching the second semiconductor layer,
wherein the first semiconductor layer comprises a portion in contact with the third semiconductor layer, a portion in contact with a side surface of the first insulating layer inside the opening, and a portion in contact with the second semiconductor layer,
wherein the second insulating layer covers the first semiconductor layer,
wherein the third conductive layer comprises a portion overlapping with the first semiconductor layer with the second insulating layer therebetween,
wherein the first semiconductor layer, the second semiconductor layer, and the third semiconductor layer comprise silicon,
wherein the second semiconductor layer and the third semiconductor layer comprise the same impurity element, and
wherein the first insulating layer comprises hydrogen, nitrogen, and silicon.

2. The semiconductor device according to claim 1,
wherein the first semiconductor layer, the second semiconductor layer, and the third semiconductor layer each comprise amorphous silicon.

3. The semiconductor device according to claim 1,
wherein the first semiconductor layer, the second semiconductor layer, and the third semiconductor layer each comprise polycrystalline silicon.

4. The semiconductor device according to claim 3,
wherein the second semiconductor layer comprises a first portion in contact with the first semiconductor layer and a second portion in contact with the first insulating layer, and
wherein a concentration of the impurity element in the first portion is higher than a concentration of the impurity element in the second portion.

5. The semiconductor device according to claim 1,
wherein the impurity element is one or more selected from phosphorus, arsenic, boron, and aluminum.

6. A method for manufacturing a semiconductor device, comprising the steps of:
forming a first conductive layer on an insulating surface and a second semiconductor layer comprising an impurity element over the first conductive layer in this order;
forming a first insulating layer to cover the second semiconductor layer;
forming a second conductive layer over the first insulating layer and a third semiconductor layer comprising the impurity element over the second conductive layer in this order;
etching part of the third semiconductor layer, part of the second conductive layer, and part of the first insulating layer to form an opening reaching the second semiconductor layer;
forming a first semiconductor layer in contact with the third semiconductor layer, the second semiconductor layer, and a side surface of the first insulating layer; and
forming a second insulating layer over the first semiconductor layer and a third conductive layer over the second insulating layer in this order,
wherein the first semiconductor layer, the second semiconductor layer, and the third semiconductor layer comprise silicon.

7. A method for manufacturing a semiconductor device, comprising the steps of:
forming a first conductive layer on an insulating surface and a second semiconductor layer over the first conductive layer in this order;
forming a first insulating layer to cover the second semiconductor layer;
forming a second conductive layer over the first insulating layer and a third semiconductor layer over the second conductive layer in this order;
etching part of the third semiconductor layer, part of the second conductive layer, and part of the first insulating layer to form an opening reaching the second semiconductor layer;
adding an impurity element to the third semiconductor layer and a portion of the second semiconductor layer that overlaps with the opening;
forming a first semiconductor layer in contact with the third semiconductor layer, the second semiconductor layer, and a side surface of the first insulating layer; and
forming a second insulating layer over the first semiconductor layer and a third conductive layer over the second insulating layer in this order,
wherein the first semiconductor layer, the second semiconductor layer, and the third semiconductor layer comprise silicon.

8. The method for manufacturing a semiconductor device, according to claim 6,
wherein one or more selected from phosphorus, arsenic, boron, and aluminum is used as the impurity element.

9. The method for manufacturing a semiconductor device, according to claim 7,
wherein one or more selected from phosphorus, arsenic, boron, and aluminum is used as the impurity element.
